(19) United States
(12) Patent Application Publication
(10) Pub. No.: US 2025/0234610 A1
(43) Pub. Date: Jul. 17, 2025

(54) LOW-RESISTANCE SOURCE/DRAIN FEATURES

(71) Applicant: Taiwan Semiconductor Manufacturing Company, Ltd., Hsinchu (TW)

(72) Inventors: Wei-Min Liu, Hsinchu (TW); Cheng-Yen Wen, Hsinchu City (TW); Ming-Hua Yu, Hsinchu City (TW); Chii-Horng Li, Hsinchu County (TW)

(21) Appl. No.: 18/656,348

(22) Filed: May 6, 2024

Related U.S. Application Data
(60) Provisional application No. 63/620,235, filed on Jan. 12, 2024.

(51) Int. Cl. H01L 29/08; H01L 21/02; H01L 21/324; H01L 29/06; H01L 29/423; H01L 29/66; H01L 29/775

(52) U.S. Cl. CPC H10D 62/151; H01L 21/02529; H01L 21/02576; H01L 21/3247; H10D 30/014; H10D 30/43; H10D 30/6735; H10D 62/121; H10D 64/018

(57) ABSTRACT

Methods of forming a low-resistance source/drain feature for a multi-gate device are provided. A example method includes forming a fin-shaped structure that includes a plurality of channel layers interleaved by a plurality of sacrificial layers, recessing a source/drain region of the fin-shaped structure to form a source/drain recess, selectively and partially recessing sidewalls of the plurality of sacrificial layers to form inner spacer recesses, forming inner spacers in the inner spacer recesses, forming a bottom dielectric layer over the substrate, depositing a first epitaxial layer over the inner spacers and the sidewalls of the plurality of the channel layers, performing a thermal treatment to reshape the first epitaxial layer, after the performing of the thermal treatment, depositing a second epitaxial layer over the first epitaxial layer. The first epitaxial layer includes germanium and the second epitaxial layer is free of germanium.

### PRIORITY DATA

This application claims priority to U.S. Provisional Patent Application No. 63/620,235 filed Jan. 12, 2024, the entirety of which is hereby incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

To improve performance of a GAA transistor, efforts are invested to develop epitaxial features that reduce leakage, capacitance and resistance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-14 illustrate fragmentary cross-sectional views of a work-in-progress (WIP) structure during a fabrication process according to the method of FIG. 1, according to one or more aspects of the present disclosure.

FIG. 15 schematically illustrates different trench bottom profiles of a multi-gate transistor fabricated using the method of FIG. 1, according to one or more aspects of the present disclosure.

FIG. 16 schematically illustrates different end surface profiles of channel members of a multi-gate transistor fabricated using the method of FIG. 1, according to one or more aspects of the present disclosure.

FIG. 17 illustrates a flowchart of a method for forming a source/drain feature of a multi-gate transistor, according to one or more aspects of the present disclosure.

FIGS. 18-21 illustrate fragmentary cross-sectional views of a WIP structure during a fabrication process according to the method of FIG. 17, according to one or more aspects of the present disclosure.

FIG. 22 illustrates a flowchart of a method for forming a source/drain feature of a multi-gate transistor, according to one or more aspects of the present disclosure.

FIGS. 23-31 illustrate fragmentary cross-sectional views of a WIP structure during a fabrication process according to the method of FIG. 22, according to one or more aspects of the present disclosure.

FIG. 32 illustrates a flowchart of a method for forming a source/drain feature of a multi-gate transistor, according to one or more aspects of the present disclosure.

FIGS. 33-36 illustrate fragmentary cross-sectional views of a WIP structure during a fabrication process according to the method of FIG. 32, according to one or more aspects of the present disclosure.

FIG. 37 illustrates a flowchart of a method for forming a source/drain feature of a multi-gate transistor, according to one or more aspects of the present disclosure.

FIGS. 38-46 illustrate fragmentary cross-sectional views of a WIP structure during a fabrication process according to the method of FIG. 37, according to one or more aspects of the present disclosure.

FIG. 47 illustrates a flowchart of a method for forming a source/drain feature of a multi-gate transistor, according to one or more aspects of the present disclosure.

FIGS. 48-51 illustrate fragmentary cross-sectional views of a WIP structure during a fabrication process according to the method of FIG. 47, according to one or more aspects of the present disclosure.

FIG. 52 illustrates a flowchart of a method for forming a source/drain feature of a multi-gate transistor, according to one or more aspects of the present disclosure.

FIGS. 53-61 illustrate fragmentary cross-sectional views of a WIP structure during a fabrication process according to the method of FIG. 52, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to multi-gate transistors and fabrication methods, and more particularly to source/drain features of GAA transistors. Channel regions of a GAA transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, GAA transistors may also be referred to as nanowire transistors or nanosheet transistors. Despite of the shapes, each of the channel members of a GAA transistor extend between and are coupled to two source/drain features. In some existing technologies, the source/drain features are epitaxially grown from end surfaces of semiconductor layers that are to be fabricated into the channel members. Owing to the faceted growth of source/drain materials, during deposition of source/drain features, voids may be formed when source/drain materials prematurely merge over unfilled space in the source/drain recess. The presence of voids reduces volume of doped source/drain materials, resulting in increased resistance. Additionally, in a subsequent process for forming source/drain contact, voids may cause overly large/deep source/drain contact openings, resulting in increased contact resistance or even electrical connection failure.

The present disclosure provides methods for forming a void-free source/drain feature. Particularly, the present disclosure provides methods forming a void-free n-type source/drain features. The n-type source/drain features forming using methods of the present disclosure includes at least one germanium-containing epitaxial layer. In some existing implementations, germanium is only present in p-type source/drain features and n-type source/drain features are free of germanium. Methods of the present disclosure thermally treat the at least one germanium-containing epitaxial layer to reshape it to have a smooth profile that is less conducive to formation of voids. The germanium content in the at least one germanium-containing epitaxial layer allows the thermal treatment to have a lower temperature range. Additionally, the germanium content in the at least one germanium-containing epitaxial layer allows it to be reshaped to have a smooth surface, rather than a faceted shape. The void-free source/drain feature of the present disclosure can result in reduced resistance and reduced contact resistance with a source/drain contact.

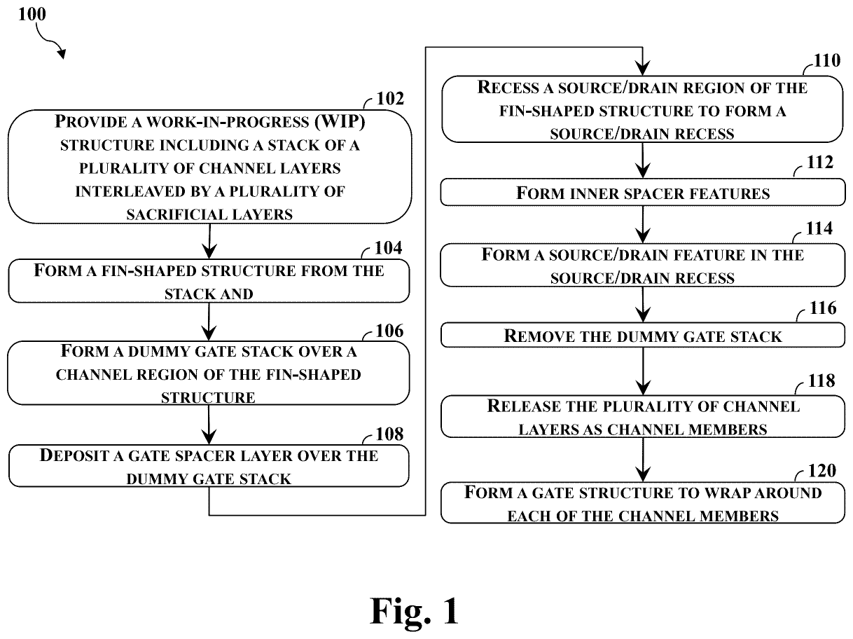

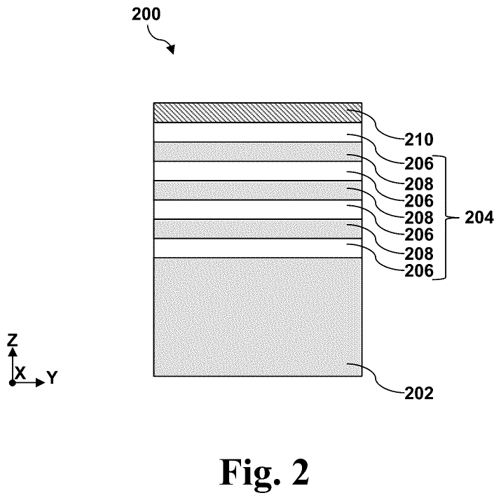

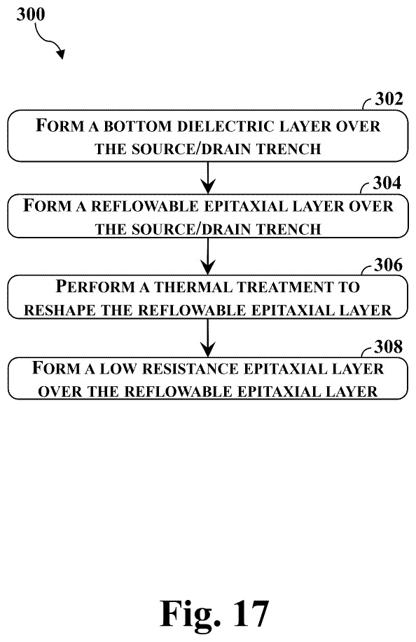

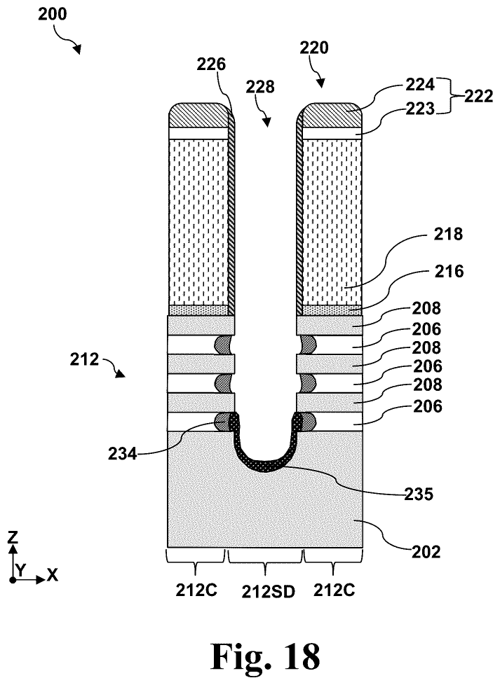

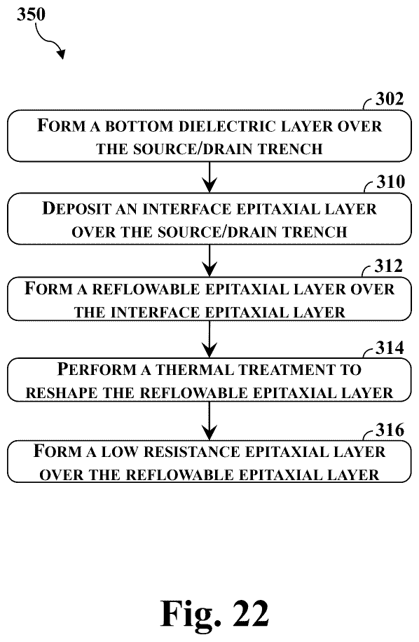

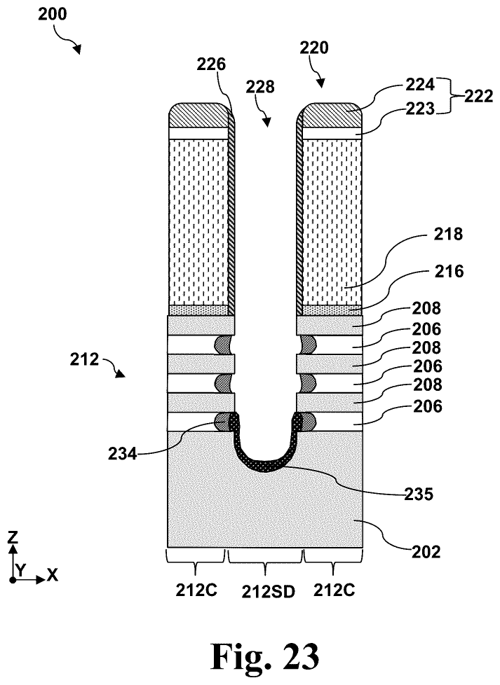

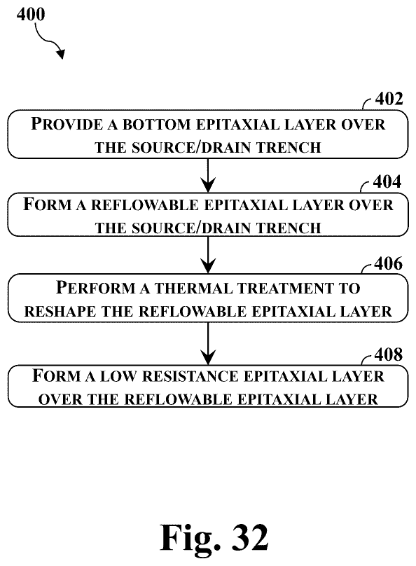

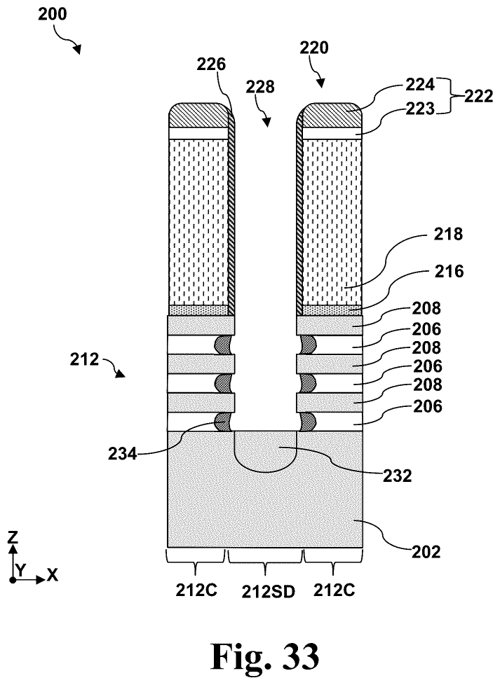

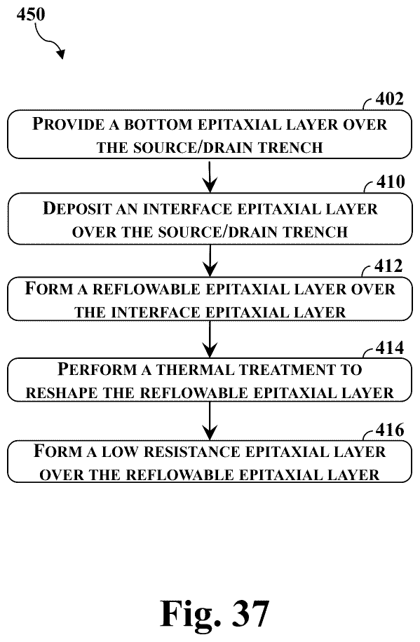

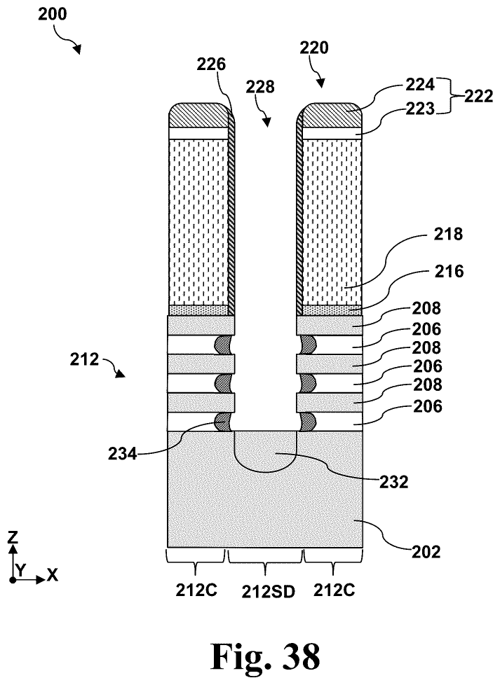

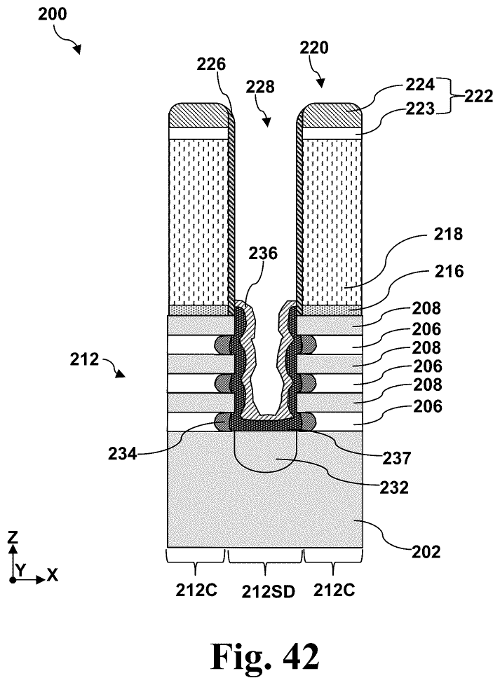

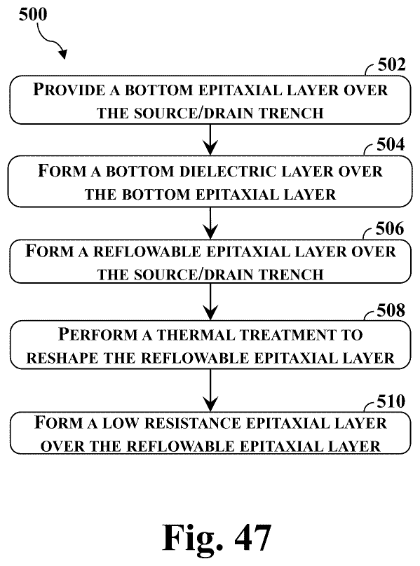

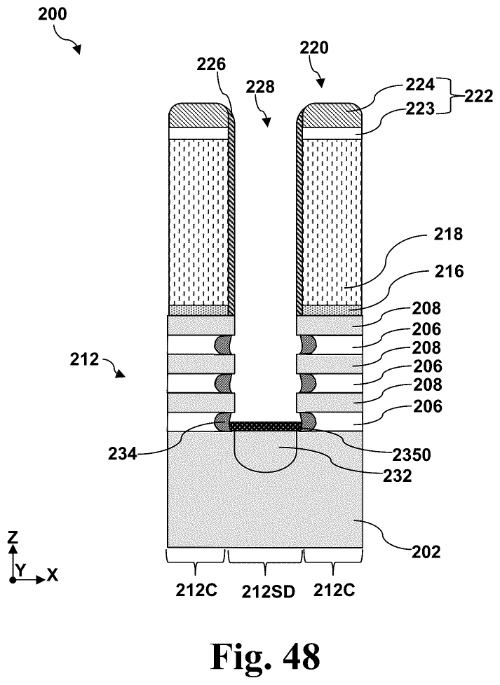

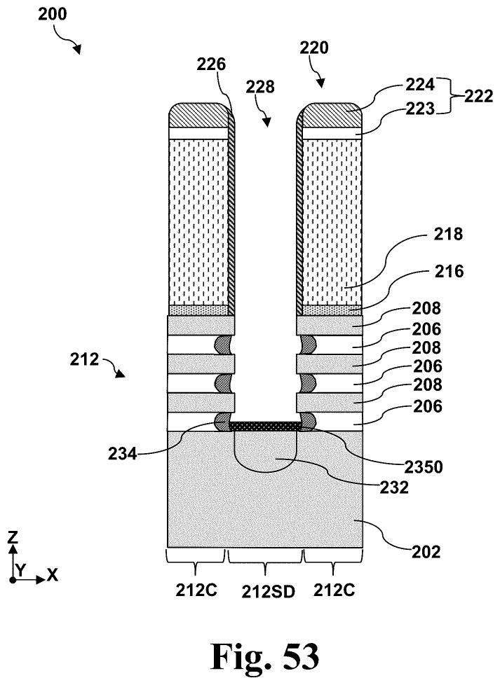

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. The semiconductor structure includes a source/drain feature and FIGS. 17, 22, 32, 37, 47, and 52 are flowcharts illustrating methods 300, 350, 400, 450, 500, and 550 of forming the source/drain feature of the semiconductor structure. Methods 100, 300, 350, 400, 450, 500, and 550 are merely examples and are not intended to limit the present disclosure to what is explicitly illustrated in method 100, 300, 350, 400, 450, 500, and 550. Additional steps can be provided before, during and after method 100, 300, 350, 400, 450, 500, or 550, and some steps described can be replaced, eliminated, or moved around for additional embodiments of the method. Not all steps are described herein in detail for reasons of simplicity. Method 100 is described below in conjunction with FIG. 2-14, which are fragmentary cross-sectional views of a WIP structure at different stages of fabrication according to embodiments of the method 100 in FIG. 1. Method 300 is described below in conjunction with FIGS. 18-21, which are fragmentary cross-sectional views of a WIP structure at different stages of fabrication according to embodiments of the method 300 in FIG. 17. Method 350 is described below in conjunction with FIGS. 23-31, which are fragmentary cross-sectional views of a WIP structure at different stages of fabrication according to embodiments of the method 350 in FIG. 22. Method 400 is described below in conjunction with FIGS. 33-36, which are fragmentary cross-sectional views of a WIP structure at different stages of fabrication according to embodiments of the method 400 in FIG. 32. Method 450 is described below in conjunction with FIGS. 38-46, which are fragmentary cross-sectional views of a WIP structure at different stages of fabrication according to embodiments of the method 450 in FIG. 37. Method 500 is described below in conjunction with FIGS. 48-51, which are fragmentary cross-sectional views of a WIP structure at different stages of fabrication according to embodiments of the method 500 in FIG. 47. Method 550 is described below in conjunction with FIGS. 53-61, which are fragmentary cross-sectional views of a WIP structure at different stages of fabrication according to embodiments of the method 550 in FIG. 42. Because the WIP structure 200 will be fabricated into a semiconductor structure or a semiconductor device, the WIP structure 200 may be referred to herein as a semiconductor structure or a semiconductor device 200 as the context requires. For avoidance, the X, Y and Z directions in FIGS. 2-14, 18-21, 23-31, 33-36, 38-46, 48-51, and 53-61 are perpendicular to one another. Throughout the present disclosure, unless expressly otherwise described, like reference numerals denote like features or steps. That is, material properties and comparisons thereof for various numbered elements described in association with a method or a figure should apply to the same numbered elements described in association with a different method or a different figure.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that four (4) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10. In the embodiments represented in FIG. 2, the stack 204 includes a bottommost sacrificial layer 206 and a topmost sacrificial layer 206. In the embodiments, the topmost sacrificial layer 206 functions to protect the topmost channel layer and may be completely consumed in subsequent processes.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

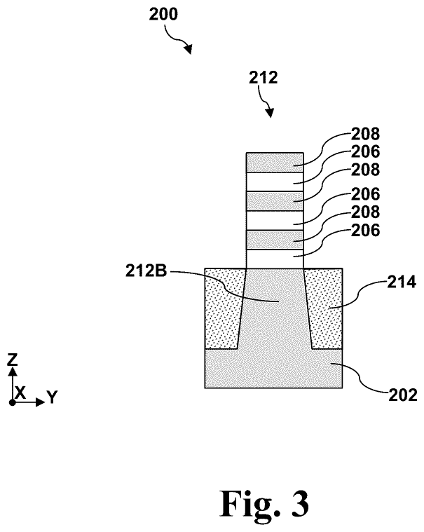

Referring to FIGS. 1, 2 and 3, method 100 includes a block 104 where a fin-shaped structure 212 is formed from the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

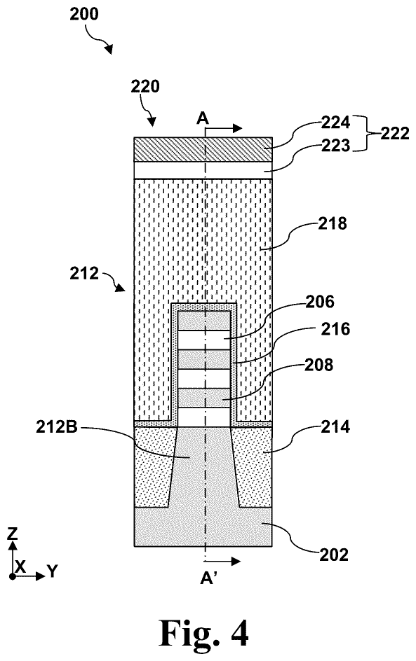

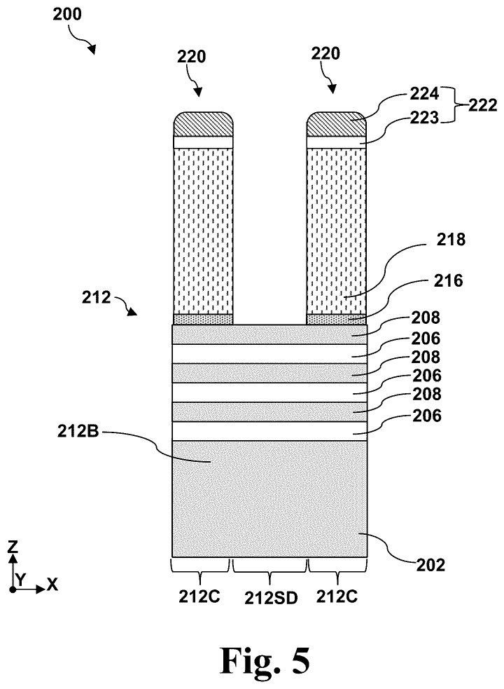

Referring to FIGS. 1, 4 and 5, method 100 includes a block 106 where a dummy gate stack 220 is formed over a channel region 212C of the fin-shaped structure 212. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the WIP structure 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

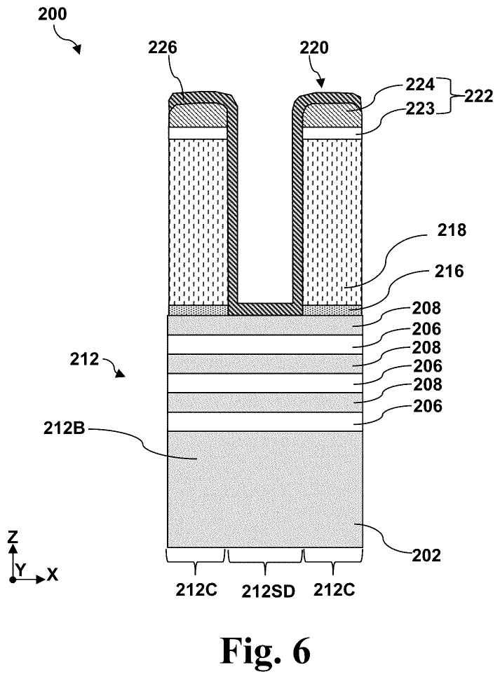

Referring to FIGS. 1 and 6, method 100 includes a block 108 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

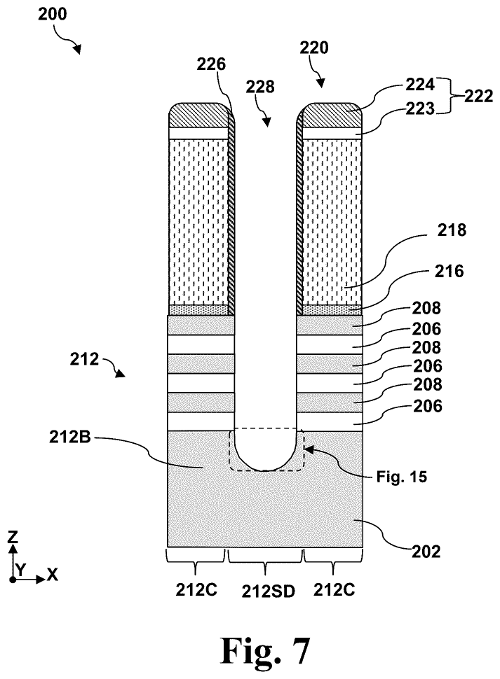

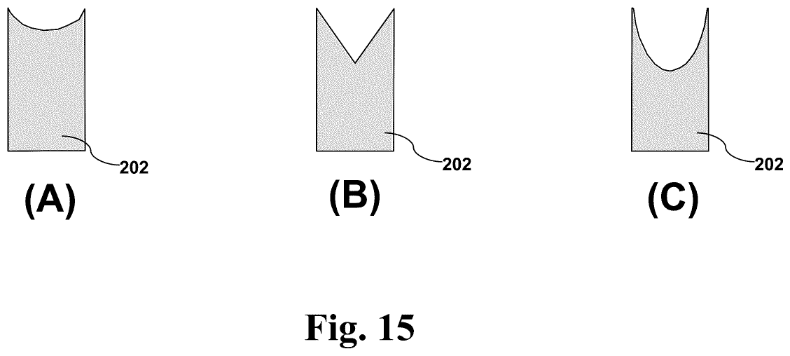

Referring to FIGS. 1 and 7, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 15, which illustrates different bottom profiles of the source/drain trenches 228 when different combinations of etchant species are selected. In some implementations where SF₆ and C₄F₈ are used in the dry etch process, a large-taper-angle bottom profile (A) may be resulted when a flow rate of C₄F₈ is greater than a flow rate of SF₆. A small-taper-angle bottom profile (C) may be resulted when a flow rate of SF₆ is greater than a flow rate of C₄F₈. The bottom profile (B) is faceted and may be resulted when when the dry etch is allowed to last longer.

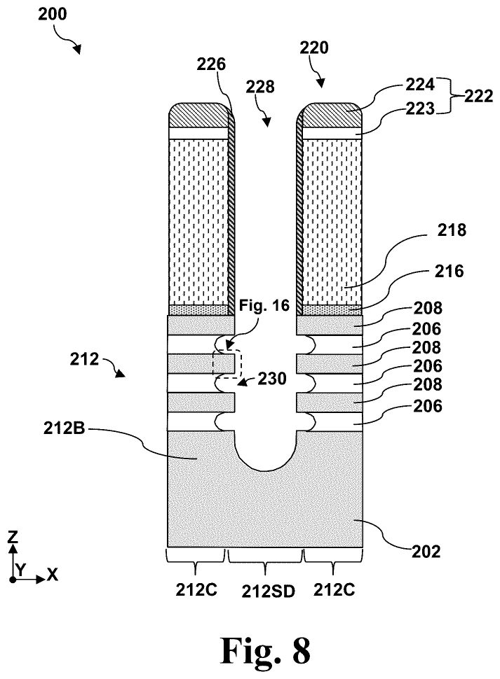

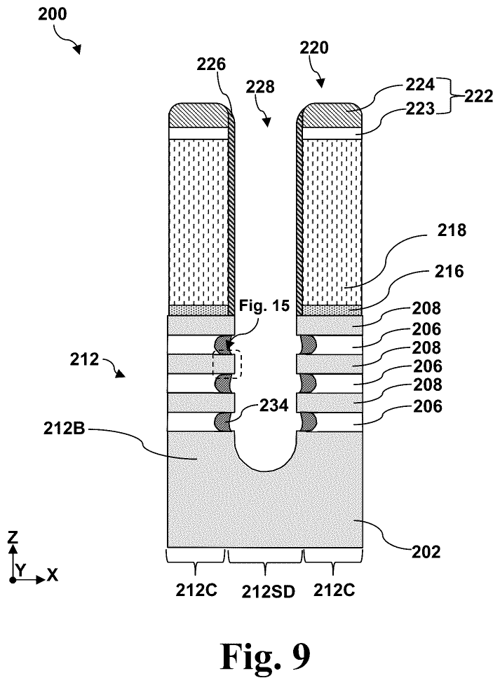

Referring to FIGS. 1, 8 and 9, method 100 includes a block 112 where inner spacer features 234 are formed. While not shown explicitly, operation at block 112 may include selective and partial removal of the sacrificial layers 206 to form inner spacer recesses 230 (shown in FIG. 8), deposition of inner spacer material over the WIP structure 200, and etch back the inner spacer material to form inner spacer features 234 in the inner spacer recesses 230 (shown in FIG. 9). Referring to FIG. 8, the sacrificial layers 206 exposed in the source/drain trenches 228 are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses 230 are formed, an inner spacer material is deposited over the WIP structure 200, including over the inner spacer recesses 230. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 234 in the inner spacer recesses 230. At block 112, the inner spacer material may also be removed from the top surfaces and/or sidewalls of the gate-top hard mask layer 222 and the gate spacer layer 226. As shown in FIG. 9, each of the inner spacer features 234 is in direct contact with the recessed sacrificial layers 206 and is disposed vertically (along the Z direction) between two neighboring channel layers 208.

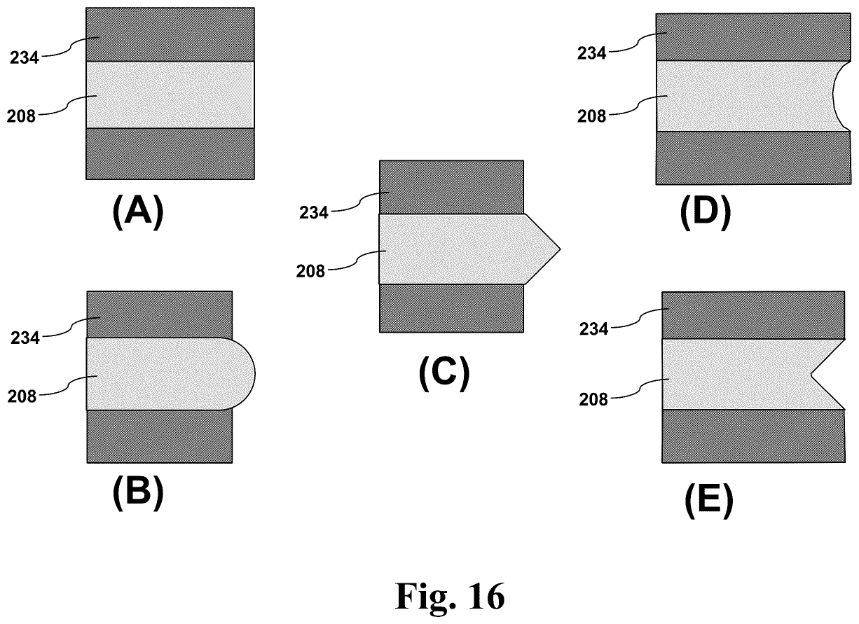

Depending on the conditions of the etching back process to form the inner spacer features 234, an end surface of each of the channel layers 208 exposed in the source/drain trench 228 shown in the dotted lines in FIG. 8 may have different cross-sectional profiles. Five (5) example cross-sectional profiles are provided in FIG. 16 are labeled as (A), (B), (C), (D), or (E). Cross-sectional profiles (B) and (C) may be formed when the etch back uses hydrogen radical in a plasma etch process. With a greater etch budget, a more protrusive cross-sectional profiles may be formed. Cross-sectional profiles (D) and (E) may be formed when the etch back uses halogen-containing species (such as chlorine-containing species or fluorine-containing species) in a plasma etch process. With a greater etch budget, a more concave cross-sectional profiles may be realized. The cross-sectional profile (A) may be formed when the etch back process uses both hydrogen radical and halogen-containing species.

While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

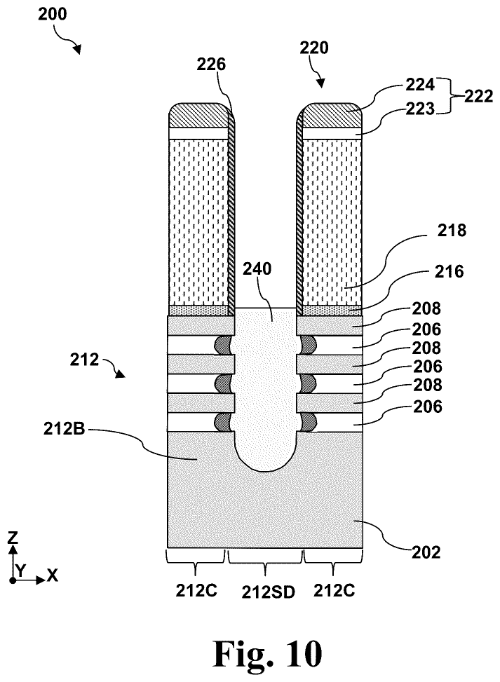

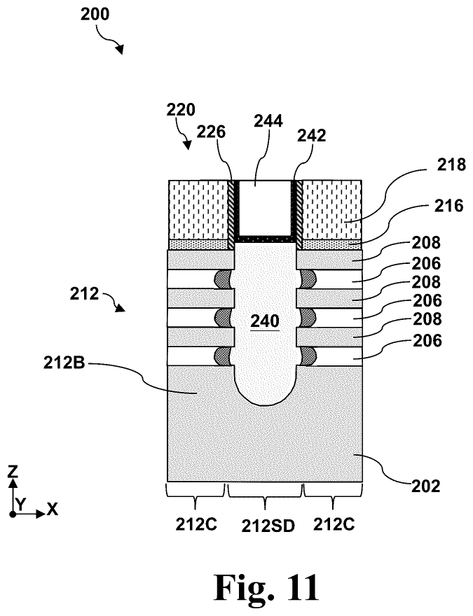

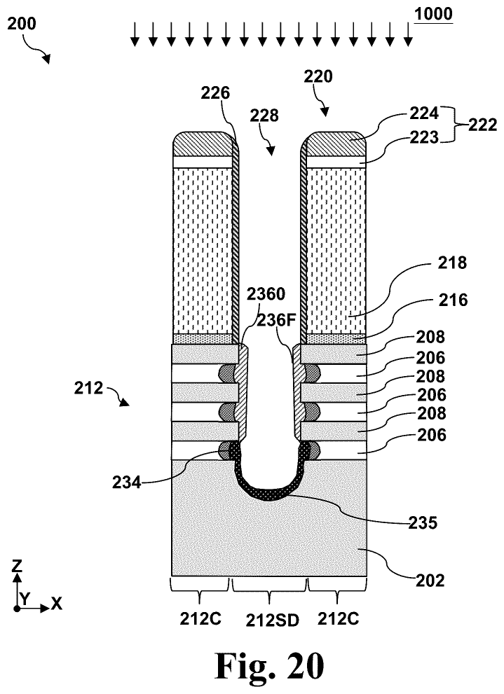

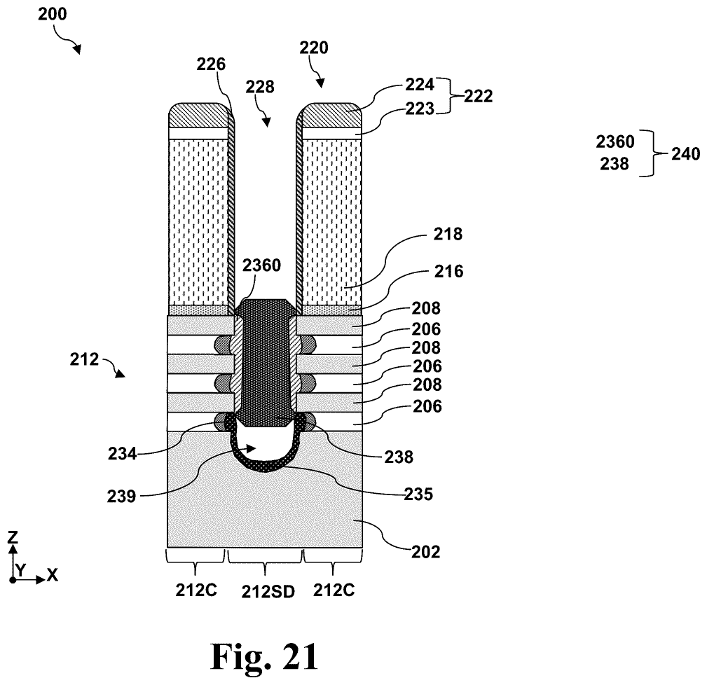

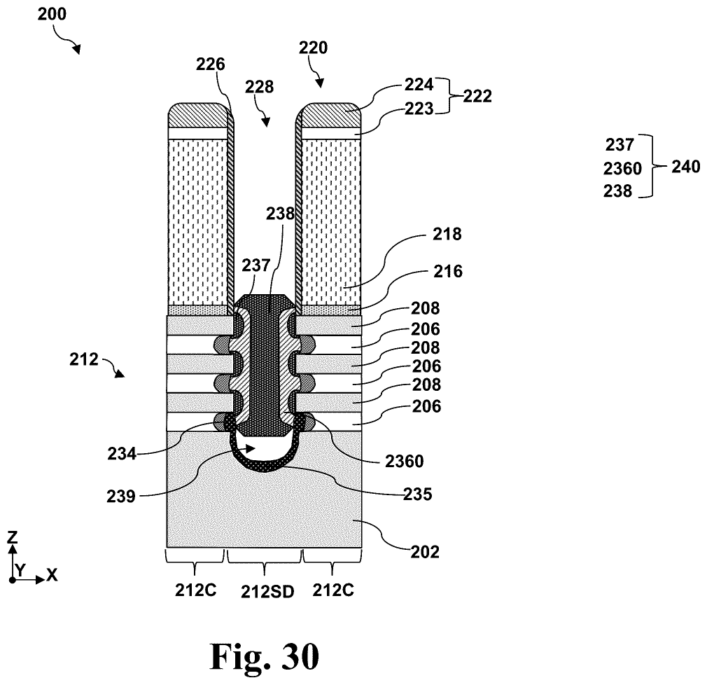

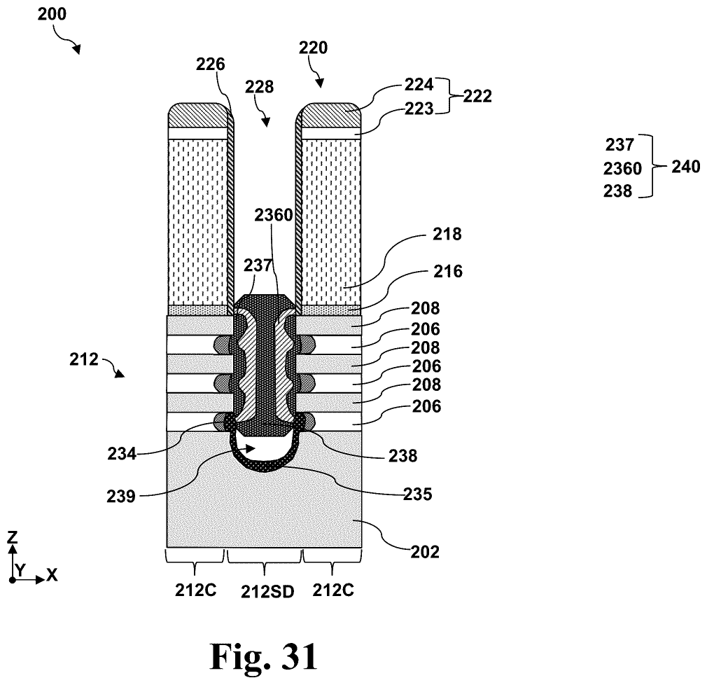

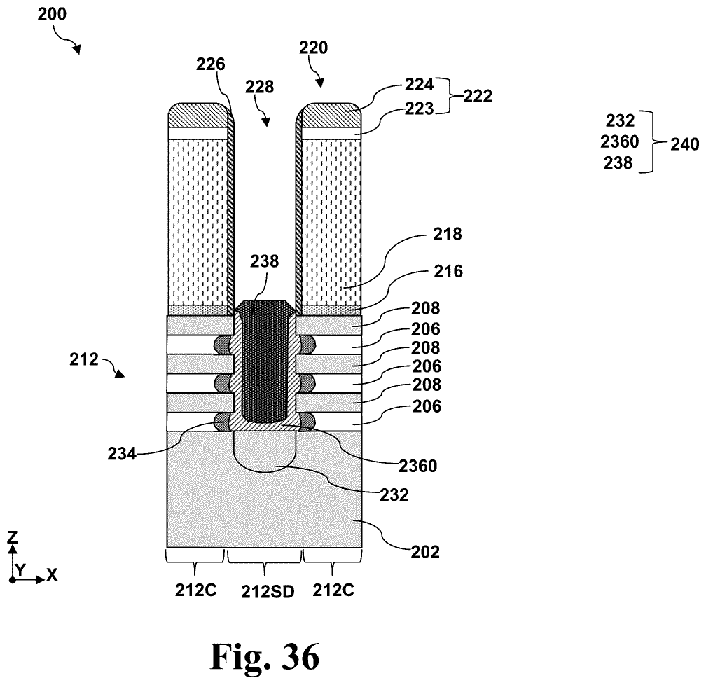

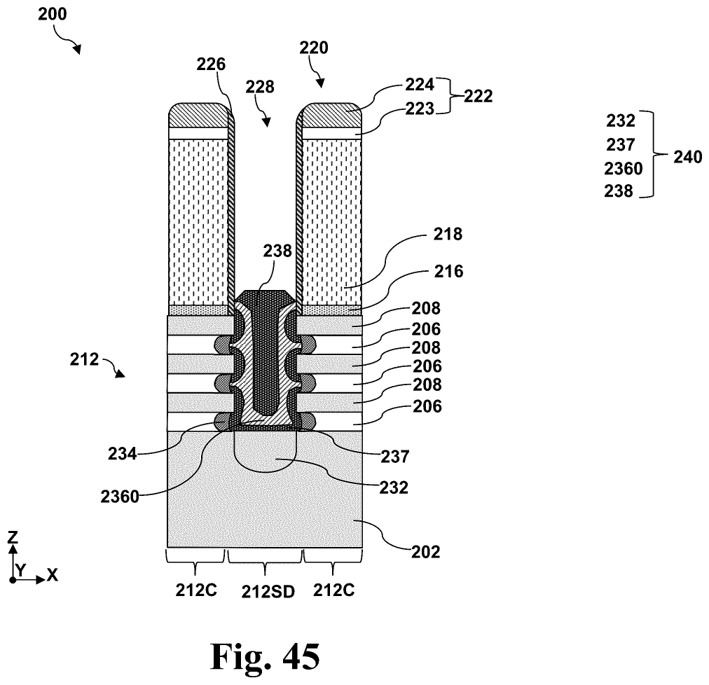

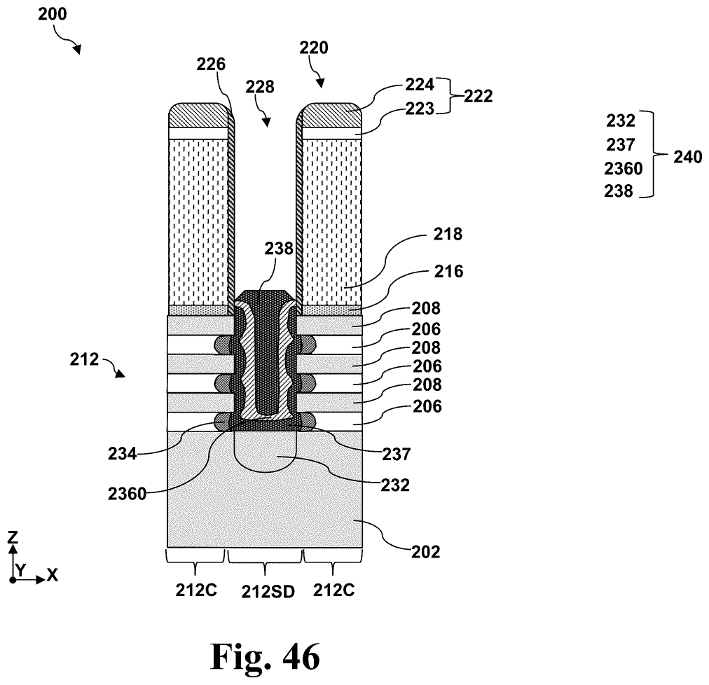

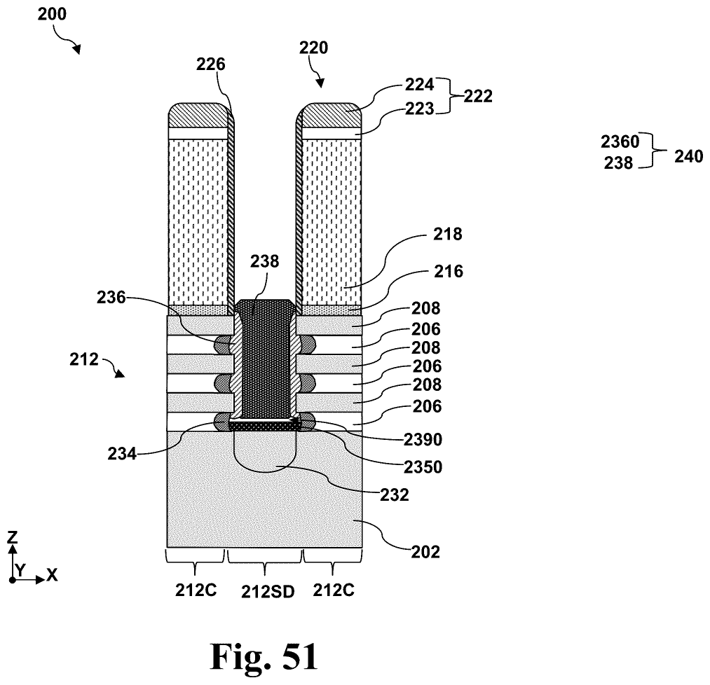

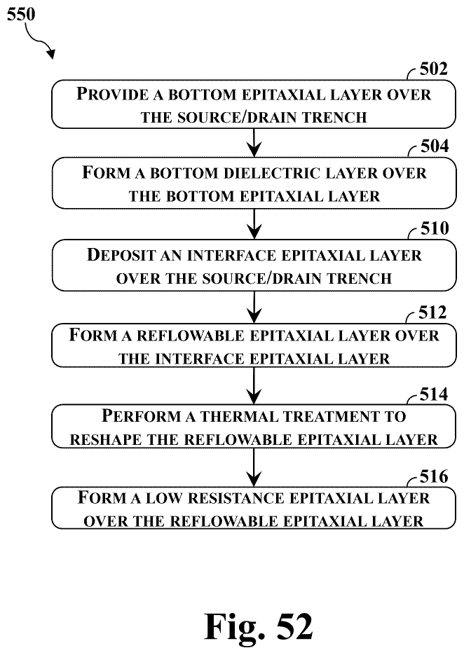

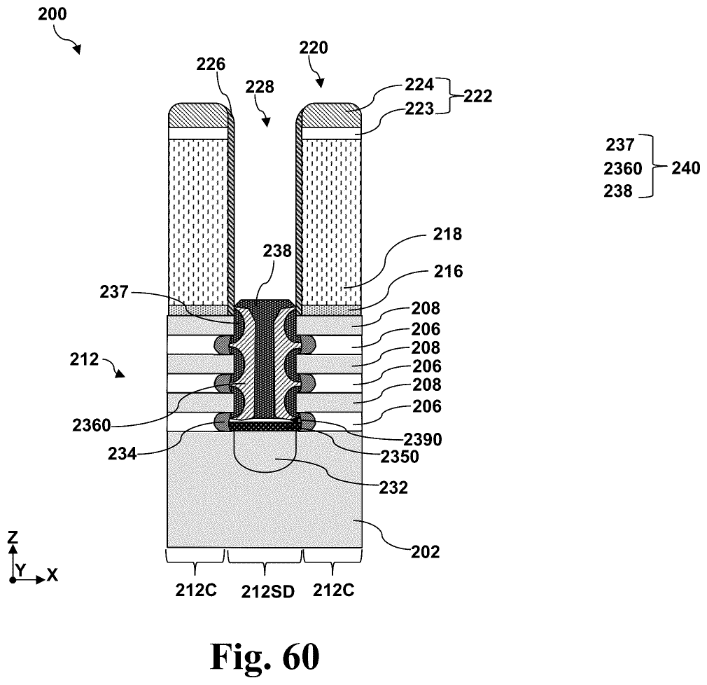

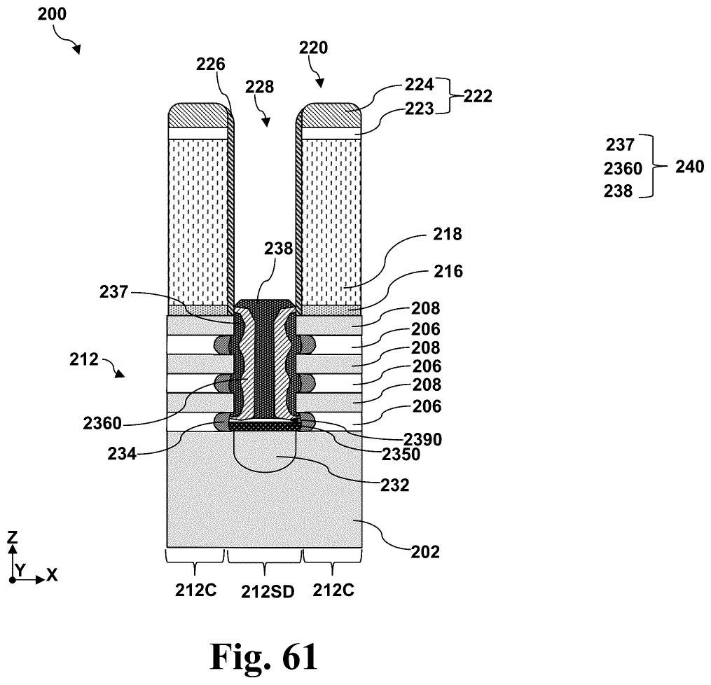

Referring to FIGS. 1 and 10, method 100 includes a block 114 where a source/drain feature 240 is formed over the source/drain region 212D. In some embodiments represented in the figures, the source/drain feature 240 is an n-type source/drain feature. The source/drain feature 240 includes multiple epitaxial layers and is doped with an n-type dopant, such as phosphorus (P), arsenic (As), antimony (Sb), or a combination thereof. At least one of the multiple epitaxial layers in the source/drain feature 240 includes silicon (Si) and germanium (Ge). At least one of the multiple epitaxial layers in the source/drain feature 240 includes silicon (Si) and is free of germanium (Ge). The source/drain feature 240 may be formed using method 300 in FIG. 17, method 350 in FIG. 22, method 400 in FIG. 32, method 450 in FIG. 37, method 500 in FIG. 47, or method 550 in FIG. 52. It should be understood that the source/drain feature 240 shown in FIG. 10 and the subsequent FIGS. 11-14 may be the source/drain feature 240 in FIG. 20 when method 300 is adopted, the source/drain feature 240 in FIG. 30 or FIG. 31 when method 350 is adopted, the source/drain feature 240 in FIG. 36 when method 400 is adopted, the source/drain feature 240 in FIG. 45 or FIG. 46 when method 450 is adopted, the source/drain feature 240 in FIG. 51 when method 500 is adopted, the source/drain feature 240 in FIG. 60 or FIG. 61 when method 550 is adopted. That is, the source/drain feature 240 shown in FIGS. 10-14 is a placeholder for the source/drain feature 240 in FIG. 21, the source/drain feature 240 in FIG. 30 or FIG. 31, the source/drain feature 240 in FIG. 36, the source/drain feature 240 in FIG. 45 or FIG. 46, the source/drain feature 240 in FIG. 51, or the source/drain feature 240 in FIG. 60 or FIG. 61. Operations to form the source/drain feature 240 according to different embodiments of the present disclosure will be described in more detail below in conjunction with FIGS. 17-61.

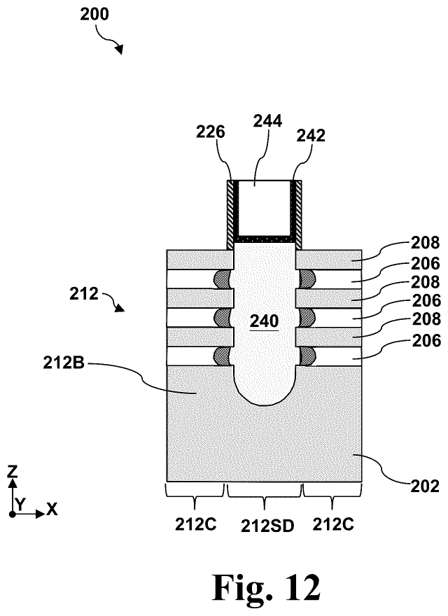

Referring to FIGS. 1 and 11-12, method 100 includes a block 116 where the dummy gate stack 220 is removed. Block 116 may include deposition of a contact etch stop layer (CESL) 242 and an interlayer dielectric (ILD) layer 244 over the source/drain feature 240 (shown in FIG. 11) and removal of the dummy gate stack 220 (shown in FIG. 12). Referring to FIG. 11, the CESL 242 is deposited over the WIP structure 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. Referring to FIG. 12, the dummy gate stack 220 is removed. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed.

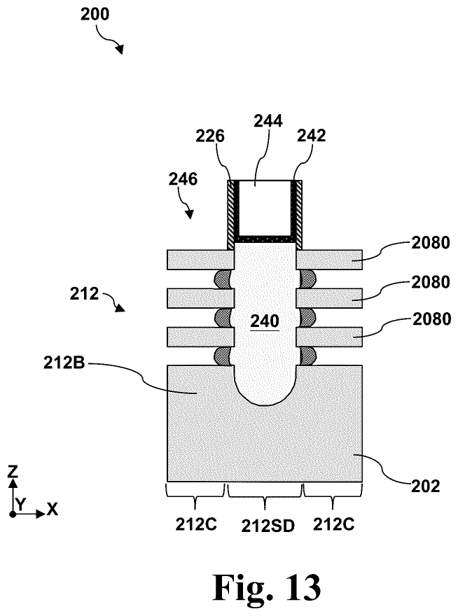

Referring to FIGS. 1 and 13, method 100 includes a block 118 where the plurality of channel layers 208 are released as channel members 2080. After the removal of the dummy gate stack 220, the sacrificial layers 206 between the channel layers 208 in the channel region 212C are selectively removed. The selective removal of the sacrificial layers 206 releases the channel layers 208 (shown in FIG. 12) to form channel members 2080 shown in FIG. 13. The selective removal of the sacrificial layers 206 forms a gate trench 246 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

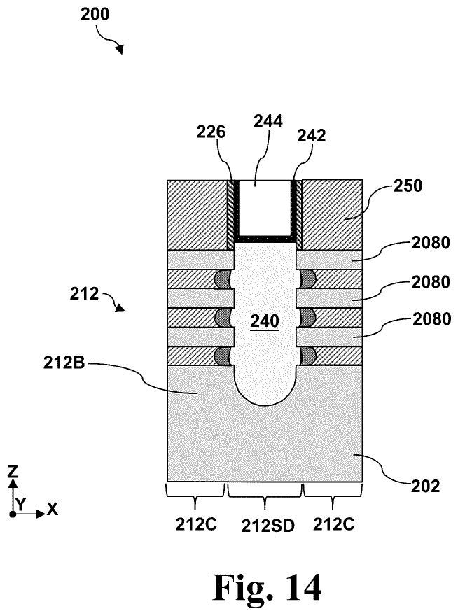

Referring to FIGS. 1 and 14, method 100 includes a block 120 where a gate structure 250 is formed to wrap around each of released as channel members 2080. After the release of the channel members 2080, the gate structure 250 is formed to wrap around each of the channel members 2080. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C.

Methods 300, 350, 400, 450, 500, and 550 in FIGS. 17, 22, 32, 37, 47, and 52 are example methods for forming the source/drain feature 240 representatively shown in FIGS. 10-14. Methods 300 and 350 include formation of a bottom dielectric layer to prevent leakage through the substrate 202. Methods 400 and 450 include formation of a bottom epitaxial layer to reduce leakage through the substrate 202. Methods 500 and 550 include formation of a bottom epitaxial layer to reduce leakage through the substrate 202 and formation of a bottom dielectric layer over the bottom epitaxial layer. By way of example and not for limitation, methods 300, 400, and 500 deposit a reflowable epitaxial layer to engage the channel layers 208. Methods 350, 350, and 550 deposit an interface epitaxial layer to engage the channel layers 208 and then form a reflowable epitaxial layer over the interface epitaxial layer. Methods 300, 350, 400, 450, 500, and 550 are described below in more detail.

Method 300 in FIG. 17 is described below in conjunction with FIGS. 18-21.

Referring to FIGS. 17 and 18, method 300 includes a block 302 where a bottom dielectric layer 235 is formed over the source/drain trench 228. In some embodiments, the bottom dielectric layer 235 includes silicon nitride, silicon carbonitride, silicon oxynitride, or silicon oxycarbonitride. In one embodiment, the bottom dielectric layer 235 is formed along with the inner spacer features 234. In this embodiment, after the dielectric material for the inner spacer features 234 is deposited over the WIP structure 200, an etch back is performed to expose end surfaces of the channel layers 208. Due to restricted access, the etch back does not completely remove the dielectric material at a bottom of the source/drain trench 228, thereby forming the bottom dielectric layer 235 covering the substrate 202 in the source/drain region 212SD. In another embodiment, the bottom dielectric layer 235 is formed in a separate process. After the inner spacer features 234 are formed, a dielectric material for the bottom dielectric layer 235 is conformally deposited over the source/drain trench 228. Afterwards, a dummy layer, such as a bottom antireflective coating (BARC) layer, is deposited over the dielectric material for the bottom dielectric layer 235. The dummy layer is then etched back to have a reduced depth. With the etched-back dummy layer protecting a bottom portion of the dielectric material, the exposed dielectric material is selectively removed. After the etched-back dummy layer is selectively removed by ashing or selective etching, the leftover bottom portion of the dielectric material becomes the bottom dielectric layer 235. The bottom dielectric layer 235 completely covers the surfaces of the substrate 202 to prevent epitaxial deposition on the substrate 202. In some embodiments represented in FIG. 18, the bottom dielectric layer 235 may partially or even completely cover sidewalls of the bottommost inner spacer features 234.

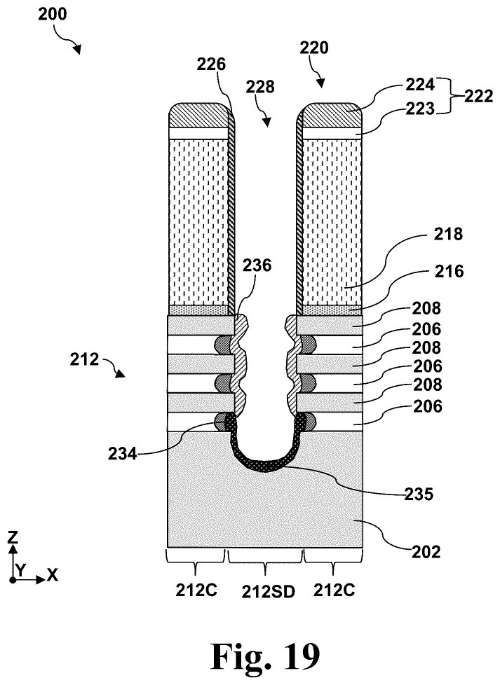

Referring to FIGS. 17 and 19, method 300 includes a block 304 where a reflowable epitaxial layer 236 is formed over the source/drain trench 228. With the bottom dielectric layer 235 covering the substrate 202, end surfaces of the channel layers 208 are the only exposed semiconductor surfaces. This allows the reflowable epitaxial layer 236 to be selectively and epitaxially deposited on the exposed semiconductor surfaces of the channel layers 208. To ensure selective deposition of the reflowable epitaxial layer 236, the reflowable epitaxial layer 236 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the reflowable epitaxial layer 236 primarily on exposed semiconductor surfaces and the etch component (or etch cycles) removes the reflowable epitaxial layer 236 deposited on non-semiconductor surfaces. In some embodiments, the selective deposition of the reflowable epitaxial layer 236 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages. As deposited, the reflowable epitaxial layer 236 includes a wavy sidewall profile. In some embodiments represented in FIG. 19, despite the use of the deposition-growth deposition process, a portion of the reflowable epitaxial layer 236 may still come in contact with the gate spacer layer 226. In some other embodiments, surfaces of the gate spacer layer 226 may be completely free of the reflowable epitaxial layer 236 with precise process control.

In some embodiments, the reflowable epitaxial layer 236 may include silicon (Si) and germanium (Ge). In some embodiments, the reflowable epitaxial layer 236 may further include carbon (C) to reduce dopant diffusion. When the reflowable epitaxial layer 236 includes carbon (C), a carbon content in the reflowable epitaxial layer 236 may be smaller than 2%. The reflowable epitaxial layer 236 may be in-situ doped with an n-type dopant, such as phosphorus (P), arsenic (As), antimony (Sb), or a combination thereof. In terms of doping concentration, an arsenic (As) concentration in the reflowable epitaxial layer 236 may be smaller than 5×10²¹ atoms/cm³, a phosphorus (P) concentration in the reflowable epitaxial layer 236 may be smaller than 5×10²¹ atoms/cm³, and a antimony (Sb) concentration in the bottom epitaxial layer 232 may be smaller than 2×10²¹ atoms/cm³. When present, doping of the arsenic (As) and antimony (Sb) in the reflowable epitaxial layer 236 is more for diffusion control and less for resistance reduction while doping of phosphorus is more for resistance reduction. It is noted that while the source/drain feature 240 is n-type, the reflowable epitaxial layer 236 includes germanium (Ge). The presence of germanium (Ge) in the reflowable epitaxial layer 236 allows it to be reshaped at a temperature between about 600° C. and about 800° C. Through experiments and simulations, it has been found that temperature required to reshape a germanium-free epitaxial layer (e.g., an epitaxial layer that includes silicon) is substantially higher, such as greater than 1000° C. Such a high process temperature tends to cause damages to the device structures that have already been formed. In some embodiments, the reflowable epitaxial layer 236 may include germanium content between about 5% and about 60%. This range is not trivial. When the germanium content is smaller than 5%, it is not sufficient to lower the flowability temperature. When the germanium content is greater than 60%, the reflowable epitaxial layer 236 may have too greater a lattice mismatch with the channel members 2080 and a defect density in the reflowable epitaxial layer 236 may be too great to outweigh the benefits brought by the germanium content.

Referring to FIGS. 17 and 20, method 300 includes a block 306 where a thermal treatment 1000 is performed to reshape the reflowable epitaxial layer 236. In some embodiments, the thermal treatment 1000 may be a chemical-free treatment or a local thermal treatment, such as laser annealing. As shown in FIG. 20, the thermal treatment 1000 is performed to the reflowable epitaxial layer 236 to cause reshaping or reflowing to form a reshaped epitaxial layer 2360. In FIG. 20, the reshaped epitaxial layer 2360 may include two opposing flat surfaces 236F that are substantially vertical to the substrate 202. As shown in FIG. 20, the flat surfaces 236F of the reshaped epitaxial layer 2360 extends substantially along a depth of the source/drain trench 228, allowing unhindered passage to the bottom dielectric layer 235. In some embodiments represented in FIG. 20, the reshaped epitaxial layer 2360 is in direct contact with and spans vertically over end surfaces of all the channel layers 208 in the channel regions 212C.

Referring to FIGS. 17 and 21, method 300 includes a block 308 where a low-resistance epitaxial layer 238 is formed over the reshaped epitaxial layer 2360. After the reflowable epitaxial layer 236 is reshaped at block 306, the low-resistance epitaxial layer 238 is selectively deposited from surfaces of the reshaped epitaxial layer 2360. In some embodiments, the low-resistance epitaxial layer 238 may be deposited using vapor-phase epitaxy (VPE), ultra-high vacuum CVD (UHV-CVD), molecular beam epitaxy (MBE), and/or other suitable processes. Because the reshaped epitaxial layer 2360 includes flat surfaces, rather than uneven shapes, the low-resistance epitaxial layer 238 is unlikely to prematurely merge to form voids in the low-resistance epitaxial layer 238. Different from the reflowable epitaxial layer 236, the low-resistance epitaxial layer 238 is not subject to a thermal treatment for reshaping and may include a smaller germanium concentration. In one embodiment, the low-resistance epitaxial layer 238 is free of germanium. In an alternative embodiment, the low-resistance epitaxial layer 238 includes silicon (Si) and carbon (C), where a carbon content in the low-resistance epitaxial layer 238 is smaller than 2%. The low-resistance epitaxial layer 238 includes an n-type dopant, such as arsenic (As), phosphorus (P), antimony (Sb), or a combination thereof. In terms of doping concentration, an arsenic (As) concentration in the low-resistance epitaxial layer 238 may be smaller than 5×10²¹ atoms/cm³, a phosphorus (P) concentration in the low-resistance epitaxial layer 238 may be smaller than 5×10²¹ atoms/cm³, and a antimony (Sb) concentration in the bottom epitaxial layer 232 may be smaller than 2×10²¹ atoms/cm³. When present, doping of the arsenic and antimony in the reflowable epitaxial layer 236 is more for diffusion control and less for resistance reduction while doping of phosphorus is more for resistance reduction. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic (As) and/or antimony (Sb), doping concentrations of arsenic and/or antimony in the reflowable epitaxial layer 236 are greater than those in the low-resistance epitaxial layer 238 because the reflowable epitaxial layer 236 is closer to the channel. In some embodiments represented in FIG. 21, a top surface of the low-resistance epitaxial layer 238 may exhibit facets during epitaxial growth. In some alternative embodiments, defects of the low-resistance epitaxial layer 238 may lead to a slanted profile (i.e., one side higher than the other) or a concave profile (i.e., being lower in the middle).

Because the resulting source/drain feature 240 has n-type conductivity, the low-resistance epitaxial layer 238 includes a greater n-type dopant concentration than the reflowable epitaxial layer 236. Empirically, a greater dopant concentration may lead to a greater defect concentration. Additionally, a germanium (Ge) concentration of the low-resistance epitaxial layer 238 is smaller than that of the reflowable epitaxial layer 236. In some implementations, the precursor for the deposition of the low-resistance epitaxial layer 238 is free of germanium (Ge). Because the low-resistance epitaxial layer 238 includes a greater dopant concentration and the reflowable epitaxial layer 236 undergoes an additional thermal treatment 1000, it may have a smaller crystallinity than the reflowable epitaxial layer 236. Because the low-resistance epitaxial layer 238 functions to lower the parasitic resistance, its volume and thickness should be maximized and are greater than those of the reflowable epitaxial layer 236.

As shown in FIG. 21, the low-resistance epitaxial layer 238 extends vertically through the flat surfaces 236F to be exposed in a void 239 defined by the low-resistance epitaxial layer 238 and the bottom dielectric layer 235. The low-resistance epitaxial layer 238 also vertically extends between the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360. When method 300 is adopted, the source/drain feature 240 includes the reshaped epitaxial layer 2360 and the low-resistance epitaxial layer 238.

Method 350 in FIG. 22 is described below in conjunction with FIGS. 23-31.

Referring to FIGS. 22 and 23, method 350 includes a block 302 where a bottom dielectric layer 235 is formed over the source/drain trench 228. Operation at block 302 has been described above with respect to method 300. Detailed description of the operations at block 302 is omitted for brevity.

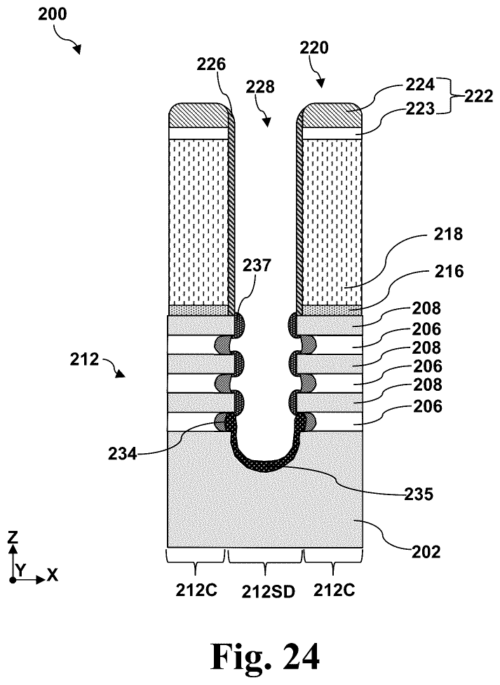

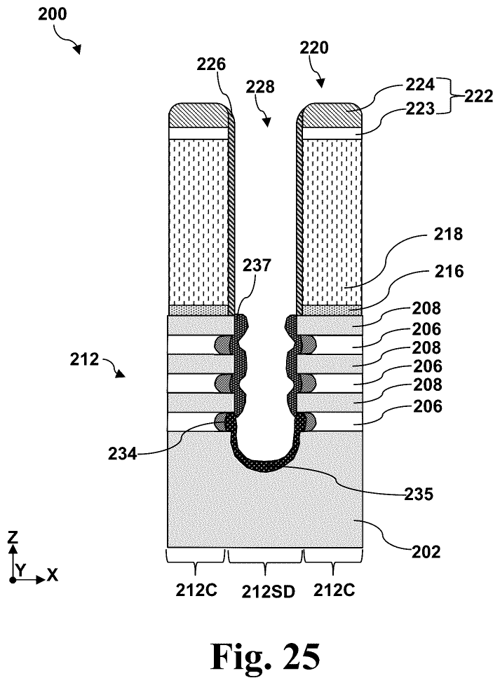

Referring to FIGS. 22, 24 and 25, method 300 includes a block 310 where an interface epitaxial layer 237 is deposited over the source/drain trench 228. With the bottom dielectric layer 235 covering the substrate 202, end surfaces of the channel layers 208 are the only exposed semiconductor surfaces. This allows the interface epitaxial layer 237 to be selectively and epitaxially deposited on the exposed semiconductor surfaces of the channel layers 208. To ensure selective deposition of the interface epitaxial layer 237, the interface epitaxial layer 237 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the interface epitaxial layer 237 primarily on exposed semiconductor surfaces and the etch component (or etch cycles) removes the interface epitaxial layer 237 deposited on non-semiconductor surfaces. In some embodiments, the selective deposition of the interface epitaxial layer 237 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages. In some embodiments represented in FIG. 24, the interface epitaxial layer 237 deposited on the end surfaces of the channel layers 208 does not merge over the inner spacer features 234. In some alternative embodiments represented in FIG. 25, the interface epitaxial layer 237 deposited on the end surfaces of the channel layers 208 merges over the inner spacer features 234. In the embodiments illustrated in FIG. 25, the interface epitaxial layer 237 may be in contact with the inner spacer features 234, except for the bottommost inner spacer features 234, which are covered by the bottom dielectric layer 235.

In some embodiments, the interface epitaxial layer 237 includes silicon (Si) and is free of germanium (Ge). In some embodiments, the interface epitaxial layer 237 may further include carbon (C) to reduce dopant out-diffusion. The interface epitaxial layer 237 may be in-situ doped with an n-type dopant, such as phosphorus (P), arsenic (As), antimony (Sb), or a combination thereof. In terms of doping concentration, n-type dopant concentration in the interface epitaxial layer 237 is smaller than that in the reflowable epitaxial layer 236 or the low-resistance epitaxial layer 238. An arsenic (As) concentration in the interface epitaxial layer 237 may be smaller than 5×10²¹ atoms/cm³, a phosphorus (P) concentration in the reflowable epitaxial layer 236 may be smaller than 5×10²¹ atoms/cm³, and a antimony (Sb) concentration in the interface epitaxial layer 237 may be smaller than 5×10²¹ atoms/cm³. When present, doping of the arsenic and antimony in the interface epitaxial layer 237 is more for diffusion control and less for resistance reduction while doping of phosphorus is more for resistance reduction. For that reason, a doping concentration of arsenic or antimony in the interface epitaxial layer 237 is greater than that in the subsequently formed reflowable epitaxial layer 236 or the low-resistance epitaxial layer 238.

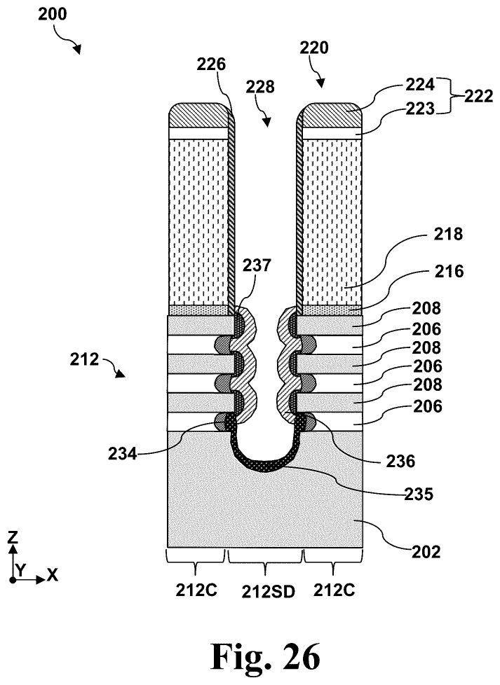

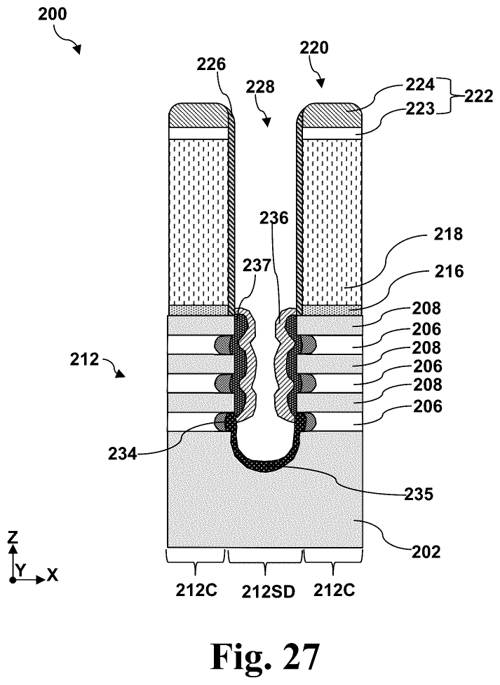

Referring to FIGS. 22, 26 and 27, method 300 includes a block 312 where a reflowable epitaxial layer 236 is formed over the interface epitaxial layer 237. Operation at block 312 is substantially similar to those described with respect to block 304 of method 300, except that, at block 312, the reflowable epitaxial layer 236 is deposited over the interface epitaxial layer 237. Detailed description of the operations at block 312 is omitted for brevity. FIG. 26 illustrates the reflowable epitaxial layer 236 deposited over the interface epitaxial layer 237 that does not merge over the inner spacer features 234. FIG. 27 illustrates the reflowable epitaxial layer 236 deposited over the interface epitaxial layer 237 that merges and spans continuously over the inner spacer features 234.

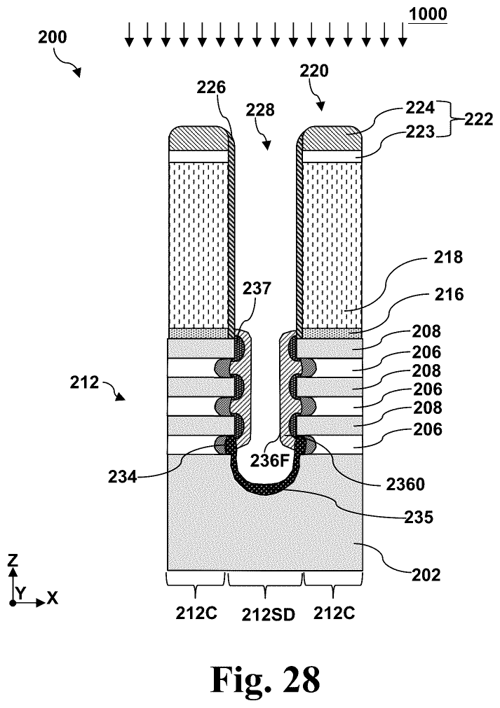

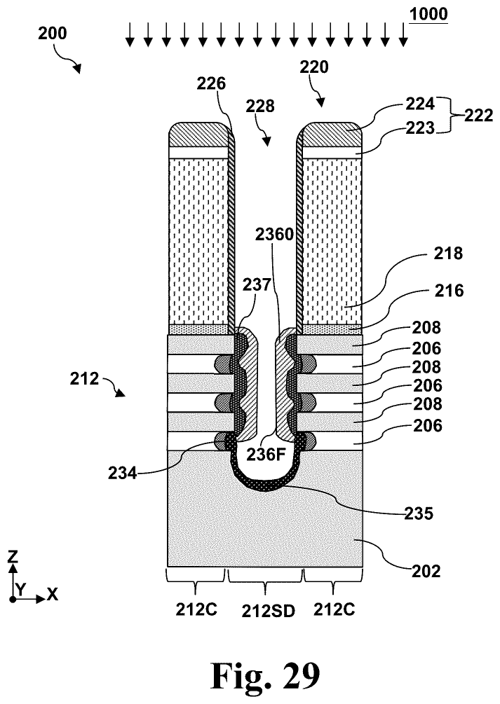

Referring to FIGS. 22, 28 and 29, method 300 includes a block 314 where a thermal treatment 1000 is performed to reshape the reflowable epitaxial layer 236. In some embodiments, the thermal treatment 1000 may be a chemical-free treatment or a local thermal treatment, such as laser annealing. As shown in FIGS. 28 and 29, the thermal treatment 1000 is performed to the reflowable epitaxial layer 236 to cause reshaping or reflowing to form a reshaped epitaxial layer 2360. FIG. 28 illustrates the reflowable epitaxial layer 236 being reshaped over the interface epitaxial layer 237 that does not merge over the inner spacer features 234. FIG. 29 illustrates the reflowable epitaxial layer 236 being reshaped over the interface epitaxial layer 237 that merges and spans continuously over the inner spacer features 234. In FIGS. 28 and 29, the reshaped epitaxial layer 2360 may include two opposing flat surfaces 236F that are substantially vertical to the substrate 202. As shown in FIGS. 28 and 29, the flat surfaces 236F of the reshaped epitaxial layer 2360 extends substantially along a depth of the source/drain trench 228, allowing unhindered passage to the bottom dielectric layer 235. In some embodiments represented in FIGS. 28 and 29, the reshaped epitaxial layer 2360 is in direct contact with and spans vertically over the interface epitaxial layer 237.

Referring to FIGS. 22, 30 and 31, method 300 includes a block 316 where a low-resistance epitaxial layer 238 is formed over the reshaped epitaxial layer 2360. Operation at block 316 is substantially similar to those described with respect to block 308 of method 300, except that, at block 316, the interface epitaxial layer 237 comes between the reshaped epitaxial layer 2360 and the channel layers 208. Detailed description of the operations at block 316 is omitted for brevity. FIG. 30 illustrates the low-resistance epitaxial layer 238 deposited over the interface epitaxial layer 237 that does not merge over the inner spacer features 234. FIG. 31 illustrates the low-resistance epitaxial layer 238 deposited over the interface epitaxial layer 237 that merges and spans continuously over the inner spacer features 234. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic and/or antimony, doping concentrations of arsenic and/or antimony in the reflowable epitaxial layer 236 are greater than those in the low-resistance epitaxial layer 238 because the reflowable epitaxial layer 236 is closer to the channel.

Compared to the interface epitaxial layer 237 and the reflowable epitaxial layer 236 that has low dopant concentrations and are subject to thermal treatment 1000, the low-resistance epitaxial layer 238 may have smaller crystallinity. Between the interface epitaxial layer 237 and the reflowable epitaxial layer 236, the interface epitaxial layer 237 may have a greater crystallinity because it directly interface the channel layers 208 and has a lower germanium (Ge) concentration than the reflowable epitaxial layer 236.

As shown in FIGS. 30 and 31, the low-resistance epitaxial layer 238 extends vertically through the flat surfaces 236F to be exposed in a void 239 defined by the low-resistance epitaxial layer 238 and the bottom dielectric layer 235. The low-resistance epitaxial layer 238 also vertically extends between the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360 and the interface epitaxial layer 237. When method 350 is adopted, the source/drain feature 240 includes the interface epitaxial layer 237, the reshaped epitaxial layer 2360 and the low-resistance epitaxial layer 238.

Method 400 in FIG. 32 is described below in conjunction with FIGS. 33-36.

Referring to FIGS. 32 and 33, method 400 includes a block 402 where a bottom epitaxial layer 232 is formed over the source/drain trench 228. At block 402, the bottom epitaxial layer 232 is selectively deposited over surfaces of the substrate 202 exposed in the source/drain trenches 228. the bottom epitaxial layer 232 functions to prevent leakage through the substrate 202. In some embodiments, the bottom epitaxial layer 232 includes undoped silicon (Si). As used herein, undoped silicon refers to silicon that is not intentionally doped in an in-situ doping process or an ion implantation process. In some alternative embodiments, the bottom epitaxial layer 232 includes silicon (Si) and is counter-doped with a p-type dopant, such as boron (B). In terms of doping concentration, a boron (B) concentration in the bottom epitaxial layer 232 may be smaller than 1×10²⁰ atoms/cm³. In still some embodiments, the bottom epitaxial layer 232 includes undoped silicon germanium (SiGe). In some alternative embodiments, the bottom epitaxial layer 232 includes silicon germanium (SiGe) and is counter-doped with a p-type dopant, such as boron (B). In terms of doping concentration, a boron (B) concentration in the bottom epitaxial layer 232 may be smaller than 1×10²⁰ atoms/cm³. While it is desirable for the bottom epitaxial layer 232 to have a level surface with the substrate 202, as shown in FIG. 33, a top surface of the bottom epitaxial layer 232 may be higher or lower than the top surface of the substrate 202. In some instances, the bottom epitaxial layer 232 may have a convex or a concave top surface profile. Because the bottom epitaxial layer 232 is epitaxially deposited on the substrate 202, which is single-crystalline, the bottom epitaxial layer 232 may be single-crystalline or substantially single-crystalline.

At block 402, in order to selectively deposit the bottom epitaxial layer 232 on the substrate 202, the bottom epitaxial layer 232 may be epitaxially deposited over the source/drain trenches 228 using silicon precursors such as silane (SiH₄) or dichlorosilane (SiH₂Cl₂), germanium precursors such as germane (GeH₄) or digermane (Ge₂H₆), and carrier gas such as nitrogen (N₂) or hydrogen (H₂). Hydrogen chloride (HCl) may be introduced to improve deposition selectivity such that little or no of the bottom epitaxial layer 232 is deposited on sidewalls of the inner spacer features 234, sidewalls of the channel layers 208, sidewalls of the gate spacer layer 226, or a top surface of the gate-top hard mask layer 222. Upon its formation, the bottom epitaxial layer 232 is in direct contact with surfaces of the substrate 202 that are exposed in the source/drain trenches 228. The bottom epitaxial layer 232 functions as a leakage reduction feature to reduce leakage current through the substrate 202.

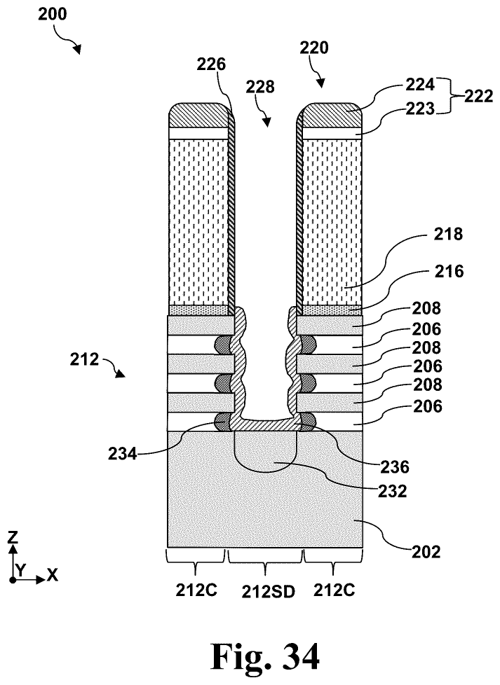

Referring to FIGS. 32 and 34, method 400 includes a block 404 where a reflowable epitaxial layer 236 is formed over the source/drain trench 228. With the bottom epitaxial layer 232 covering the substrate 202, a top surface of the bottom epitaxial layer 232 and end surfaces of the channel layers 208 account for exposed semiconductor surfaces in the source/drain trench 228. This allows the reflowable epitaxial layer 236 to be selectively and epitaxially deposited on the exposed semiconductor surfaces of the channel layers 208 and the top surface of the bottom epitaxial layer 232. To ensure selective deposition of the reflowable epitaxial layer 236, the reflowable epitaxial layer 236 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the reflowable epitaxial layer 236 primarily on exposed semiconductor surfaces and the etch component (or etch cycles) removes the reflowable epitaxial layer 236 deposited on non-semiconductor surfaces. In some embodiments, the selective deposition of the reflowable epitaxial layer 236 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages.

In some embodiments, the reflowable epitaxial layer 236 may include silicon (Si) and germanium (Ge). In some embodiments, the reflowable epitaxial layer 236 may further include carbon (C) to reduce dopant diffusion. When the reflowable epitaxial layer 236 includes carbon (C), a carbon content in the reflowable epitaxial layer 236 may be smaller than 2%. The reflowable epitaxial layer 236 may be in-situ doped with an n-type dopant, such as phosphorus (P), arsenic (As), antimony (Sb), or a combination thereof. In terms of doping concentration, an arsenic (As) concentration in the reflowable epitaxial layer 236 may be smaller than 5×10²¹ atoms/cm³, a phosphorus (P) concentration in the reflowable epitaxial layer 236 may be smaller than 5×10²¹ atoms/cm³, and a antimony (Sb) concentration in the bottom epitaxial layer 232 may be smaller than 2×10²¹ atoms/cm³. When present, doping of the arsenic (As) and antimony (Sb) in the reflowable epitaxial layer 236 is more for diffusion control and less for resistance reduction while doping of phosphorus is more for resistance reduction. It is noted that while the source/drain feature 240 is n-type, the reflowable epitaxial layer 236 includes germanium (Ge). The presence of germanium (Ge) in the reflowable epitaxial layer 236 allows it to be reshaped at a temperature between about 600° C. and about 800° C. Through experiments and simulations, it has been found that temperature required to reshape a germanium-free epitaxial layer (e.g., an epitaxial layer that includes silicon) is substantially higher, such as greater than 1000° C. Such a high process temperature tends to cause damages to the device structures that have already been formed. In some embodiments, the reflowable epitaxial layer 236 may include germanium content between about 5% and about 60%. This range is not trivial. When the germanium content is smaller than 5%, it is not sufficient to lower the flowability temperature. When the germanium content is greater than 60%, the reflowable epitaxial layer 236 may have too greater a lattice mismatch with the channel members 2080 and a defect density in the reflowable epitaxial layer 236 may be too great to outweigh the benefits brought by the germanium content.

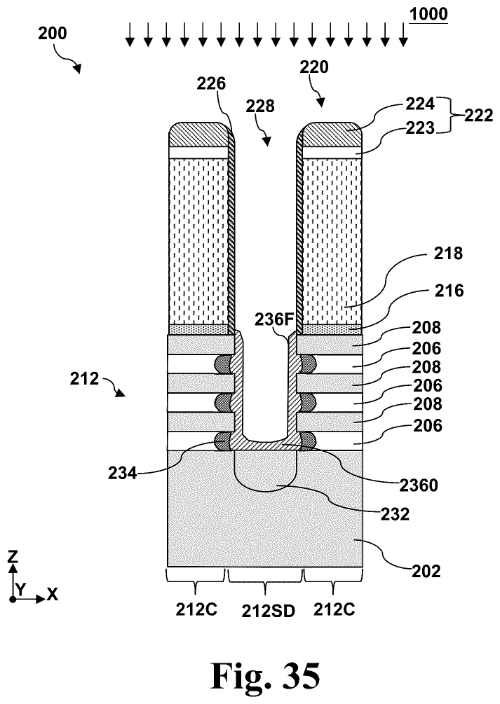

Referring to FIGS. 32 and 35, method 400 includes a block 406 where a thermal treatment 1000 is performed to reshape the reflowable epitaxial layer 236. In some embodiments, the thermal treatment 1000 may be a chemical-free treatment or a local thermal treatment, such as laser annealing. As shown in FIG. 35, the thermal treatment 1000 is performed to the reflowable epitaxial layer 236 to cause reshaping or reflowing to form a reshaped epitaxial layer 2360. In FIG. 35, the reshaped epitaxial layer 2360 may include two opposing flat surfaces 236F that are substantially vertical to the substrate 202. As shown in FIG. 35, the flat surfaces 236F of the reshaped epitaxial layer 2360 extends substantially along a depth of the source/drain trench 228, allowing unhindered passage to the bottom dielectric layer 235. In some embodiments represented in FIG. 35, the reshaped epitaxial layer 2360 is in direct contact with and spans vertically over end surfaces of all the channel layers 208 in the channel regions 212C.

Referring to FIGS. 32 and 36, method 400 includes a block 408 where a low-resistance epitaxial layer 238 is formed over the reshaped epitaxial layer 2360. After the reflowable epitaxial layer 236 is reshaped at block 406, the low-resistance epitaxial layer 238 is selectively deposited from surfaces of the reshaped epitaxial layer 2360. In some embodiments, the low-resistance epitaxial layer 238 may be deposited using vapor-phase epitaxy (VPE), ultra-high vacuum CVD (UHV-CVD), molecular beam epitaxy (MBE), and/or other suitable processes. Because the reshaped epitaxial layer 2360 includes flat surfaces, rather than uneven shapes, the low-resistance epitaxial layer 238 is unlikely to prematurely merge to form voids in the low-resistance epitaxial layer 238. Different from the reflowable epitaxial layer 236, low-resistance epitaxial layer 238 is not subject to a thermal treatment for reshaping. In one embodiment, the low-resistance epitaxial layer 238 is free of germanium. In an alternative embodiment, the low-resistance epitaxial layer 238 includes silicon (Si) and carbon (C), where a carbon content in the low-resistance epitaxial layer 238 is smaller than 2%. The low-resistance epitaxial layer 238 includes an n-type dopant, such as arsenic (As), phosphorus (P), antimony (Sb), or a combination thereof. In terms of doping concentration, an arsenic (As) concentration in the low-resistance epitaxial layer 238 may be smaller than 5×10²¹ atoms/cm³, a phosphorus (P) concentration in the low-resistance epitaxial layer 238 may be smaller than 5×10²¹ atoms/cm³, and a antimony (Sb) concentration in the bottom epitaxial layer 232 may be smaller than 2×10²¹ atoms/cm³. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic and/or antimony, doping concentrations of arsenic and/or antimony in the reflowable epitaxial layer 236 are greater than those in the low-resistance epitaxial layer 238 because the reflowable epitaxial layer 236 is closer to the channel.

As shown in FIG. 36, the low-resistance epitaxial layer 238 extends vertically along the flat surfaces 236F into the reshaped epitaxial layer 2360. The low-resistance epitaxial layer 238 also vertically extends between a plurality of the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360. The low-resistance epitaxial layer 238 is spaced apart from the bottom epitaxial layer 232 by the reshaped epitaxial layer 2360.

Method 450 in FIG. 37 is described below in conjunction with FIGS. 38-46.

Referring to FIGS. 37 and 38, method 450 includes a block 402 where a bottom epitaxial layer 232 is formed over the source/drain trench 228. Operation at block 402 has been described above with respect to method 400. Detailed description of the operations at block 402 is omitted for brevity.

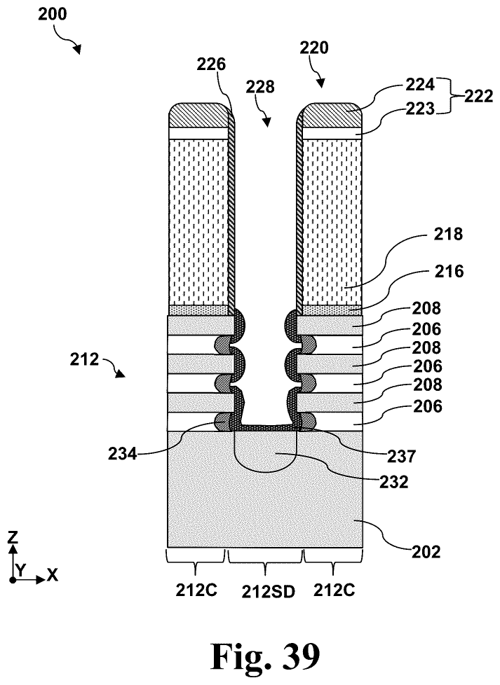

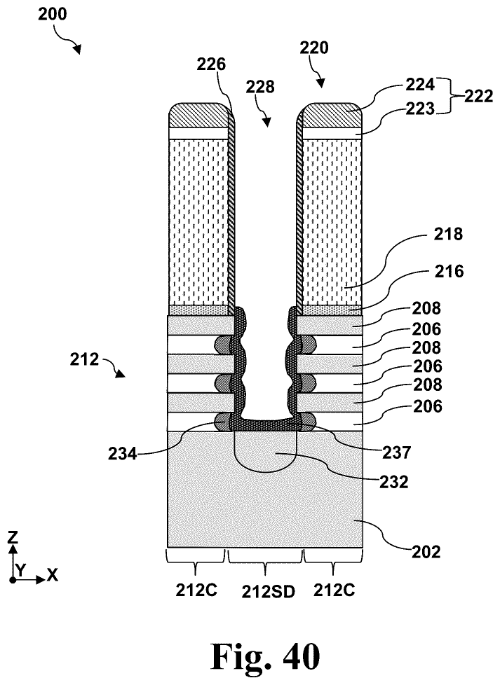

Referring to FIGS. 37, 39 and 40, method 450 includes a block 410 where an interface epitaxial layer 237 is deposited over the source/drain trench 228. With the bottom epitaxial layer 232 covering the substrate 202, a top surface of the bottom epitaxial layer 232 and end surfaces of the channel layers 208 account for exposed semiconductor surfaces in the source/drain trench 228. This allows the interface epitaxial layer 237 to be selectively and epitaxially deposited on the exposed semiconductor surfaces of the channel layers 208 and on the bottom epitaxial layer 232. To ensure selective deposition of the interface epitaxial layer 237, the interface epitaxial layer 237 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the interface epitaxial layer 237 primarily on exposed semiconductor surfaces and the etch component (or etch cycles) removes the interface epitaxial layer 237 deposited on non-semiconductor surfaces. In some embodiments, the selective deposition of the interface epitaxial layer 237 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages. In some embodiments represented in FIG. 39, the interface epitaxial layer 237 deposited on the end surfaces of the channel layers 208 does not merge over the inner spacer features 234. In some alternative embodiments represented in FIG. 40, the interface epitaxial layer 237 deposited on the end surfaces of the channel layers 208 merges over the inner spacer features 234. In the embodiments illustrated in FIG. 40, the interface epitaxial layer 237 may be in contact with the inner spacer features 234, except for the bottommost inner spacer features 234, which are covered by the bottom dielectric layer 235.

In some embodiments, the interface epitaxial layer 237 includes silicon (Si) and is free of germanium (Ge). In some embodiments, the interface epitaxial layer 237 may further include carbon (C) to reduce dopant out-diffusion. The interface epitaxial layer 237 may be in-situ doped with an n-type dopant, such as phosphorus (P), arsenic (As), antimony (Sb), or a combination thereof. In terms of doping concentration, n-type dopant concentration in the interface epitaxial layer 237 is smaller than that in the reflowable epitaxial layer 236 or the low-resistance epitaxial layer 238. An arsenic (As) concentration in the interface epitaxial layer 237 may be smaller than 5×10²¹ atoms/cm³, a phosphorus (P) concentration in the reflowable epitaxial layer 236 may be smaller than 5×10²¹ atoms/cm³, and a antimony (Sb) concentration in the interface epitaxial layer 237 may be smaller than 5×10²¹ atoms/cm³. When present, doping of the arsenic and antimony in the interface epitaxial layer 237 is more for diffusion control and less for resistance reduction while doping of phosphorus is more for resistance reduction. For that reason, a doping concentration of arsenic or antimony in the interface epitaxial layer 237 is greater than that in the subsequently formed reflowable epitaxial layer 236 or the low-resistance epitaxial layer 238.

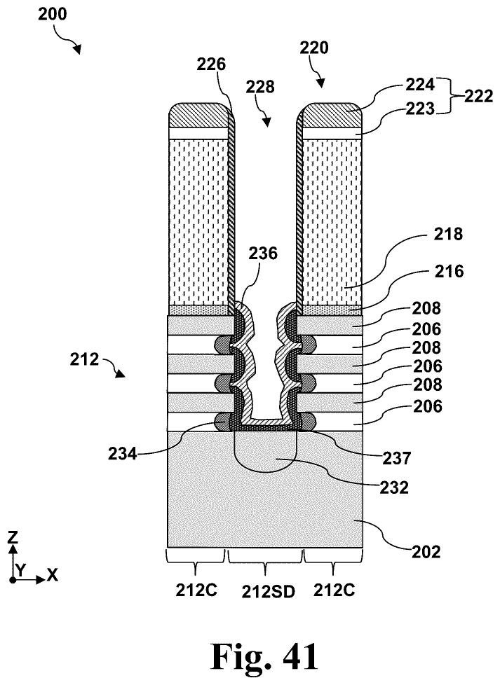

Referring to FIGS. 37, 41 and 42, method 450 includes a block 412 where a reflowable epitaxial layer 236 is formed over the interface epitaxial layer 237. Operation at block 412 is substantially similar to those described with respect to block 304 of method 300, except that, at block 412, the reflowable epitaxial layer 236 is deposited over the interface epitaxial layer 237. Detailed description of the operations at block 412 is omitted for brevity. FIG. 41 illustrates the reflowable epitaxial layer 236 deposited over the interface epitaxial layer 237 that does not merge over the inner spacer features 234. FIG. 42 illustrates the reflowable epitaxial layer 236 deposited over the interface epitaxial layer 237 that merges and spans continuously over the inner spacer features 234.

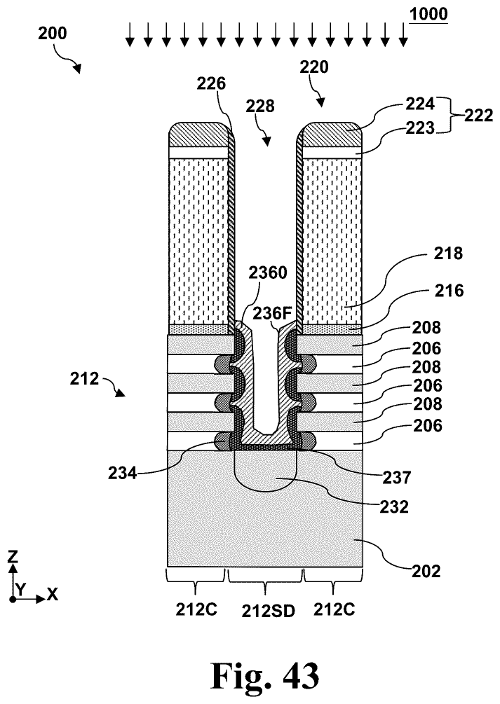

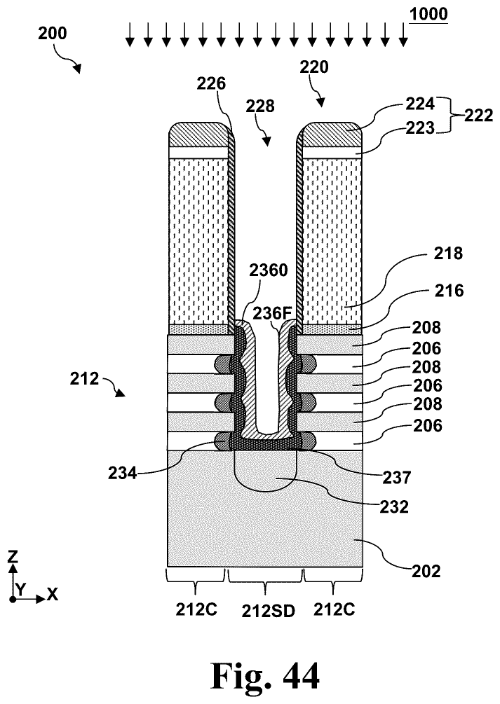

Referring to FIGS. 37, 43 and 44, method 450 includes a block 414 where a thermal treatment 1000 is performed to reshape the reflowable epitaxial layer 236. In some embodiments, the thermal treatment 1000 may be a chemical-free treatment or a local thermal treatment, such as laser annealing. As shown in FIGS. 43 and 44, the thermal treatment 1000 is performed to the reflowable epitaxial layer 236 to cause reshaping or reflowing to form a reshaped epitaxial layer 2360. FIG. 43 illustrates the reflowable epitaxial layer 236 being reshaped over the interface epitaxial layer 237 that does not merge over the inner spacer features 234. FIG. 44 illustrates the reflowable epitaxial layer 236 being reshaped over the interface epitaxial layer 237 that merges and spans continuously over the inner spacer features 234. In FIGS. 43 and 44, the reshaped epitaxial layer 2360 may include two opposing flat surfaces 236F that are substantially vertical to the substrate 202. As shown in FIGS. 43 and 44, the flat surfaces 236F of the reshaped epitaxial layer 2360 extends substantially along a depth of the source/drain trench 228, allowing unhindered passage to a bottom surface of the reshaped epitaxial layer 2360.

Referring to FIGS. 37, 45 and 46, method 450 includes a block 416 where a low-resistance epitaxial layer 238 is formed over the reshaped epitaxial layer 2360. After the reflowable epitaxial layer 236 is reshaped at block 414, the low-resistance epitaxial layer 238 is selectively deposited from surfaces of the reshaped epitaxial layer 2360. In some embodiments, the low-resistance epitaxial layer 238 may be deposited using vapor-phase epitaxy (VPE), ultra-high vacuum CVD (UHV-CVD), molecular beam epitaxy (MBE), and/or other suitable processes. Compared to the reflowable epitaxial layer 236, the low-resistance epitaxial layer 238 comprises a greater dopant concentration to reduce parasitic resistance. Because the reshaped epitaxial layer 2360 includes flat surfaces, rather than uneven shapes, the low-resistance epitaxial layer 238 is unlikely to prematurely merge to form voids in the low-resistance epitaxial layer 238. Different from the reflowable epitaxial layer 236, low-resistance epitaxial layer 238 is not subject to a thermal treatment for reshaping. In one embodiment, the low-resistance epitaxial layer 238 is free of germanium. In an alternative embodiment, the low-resistance epitaxial layer 238 includes silicon (Si) and carbon (C), where a carbon content in the low-resistance epitaxial layer 238 is smaller than 2%. The low-resistance epitaxial layer 238 includes an n-type dopant, such as arsenic (As), phosphorus (P), antimony (Sb), or a combination thereof. In terms of doping concentration, an arsenic (As) concentration in the low-resistance epitaxial layer 238 may be smaller than 5×10²¹ atoms/cm³, a phosphorus (P) concentration in the low-resistance epitaxial layer 238 may be smaller than 5×10²¹ atoms/cm³, and a antimony (Sb) concentration in the low-resistance epitaxial layer 238 may be smaller than 5×10²¹ atoms/cm³. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic and/or antimony, doping concentrations of arsenic and/or antimony in the reflowable epitaxial layer 236 are greater than those in the low-resistance epitaxial layer 238 because the reflowable epitaxial layer 236 is closer to the channel.

As shown in FIGS. 45 and 46, the low-resistance epitaxial layer 238 extends vertically along the flat surfaces 236F into the reshaped epitaxial layer 2360. The low-resistance epitaxial layer 238 also vertically extends between a plurality of the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360 and the interface epitaxial layer 237. The low-resistance epitaxial layer 238 is spaced apart from the bottom epitaxial layer 232 by the reshaped epitaxial layer 2360 and the interface epitaxial layer 237. When method 450 is adopted, the source/drain feature 240 includes the bottom epitaxial layer 232, the interface epitaxial layer 237, the reshaped epitaxial layer 2360, and the low-resistance epitaxial layer 238.

Method 500 in FIG. 47 is described below in conjunction with FIGS. 48-51.

Referring to FIGS. 47 and 48, method 500 includes a block 502 where a bottom epitaxial layer 232 is formed over the source/drain trench 228. Operation at block 502 is similar to those at block 402 described above respect to method 400, except that the bottom epitaxial layer 232 in method 500 is not counter-doped. As will described below, a bottom dielectric layer 2350 is going to cover the top surface of the bottom epitaxial layer 232. Because the bottom dielectric layer 2350 is sufficient to block off or reduce leakage into the substrate 202, the bottom epitaxial layer 232 may be undoped and counter-doping is not necessary.

Referring to FIGS. 47 and 48, method 500 includes a block 504 where a bottom dielectric layer 2350 is formed over the source/drain trench 228. In some embodiments, the bottom dielectric layer 2350 includes silicon nitride, silicon carbonitride, silicon oxynitride, or silicon oxycarbonitride. Different from the bottom dielectric layer 235 formed in methods 300 and 350, the bottom dielectric layer 2350 is formed after and on the bottom epitaxial layer 232. As such, the bottom dielectric layer 2350 is not formed along with the inner spacer features 234. In some embodiments, after the inner spacer features 234 are formed, a dielectric material for the bottom dielectric layer 2350 is conformally deposited over the source/drain trench 228 and the bottom epitaxial layer 232. Afterwards, a dummy layer, such as a bottom antireflective coating (BARC) layer, is deposited over the dielectric material for the bottom dielectric layer 2350. The dummy layer is then etched back to have a reduced depth such that end surfaces of the channel layers 208 are exposed in the source/drain trench 228. With the etched-back dummy layer protecting a bottom portion of the dielectric material, the exposed dielectric material is selectively removed. After the etched-back dummy layer is selectively removed by stripping, ashing or selective etching, the leftover bottom portion of the dielectric material becomes the bottom dielectric layer 2350. The bottom dielectric layer 235 may completely cover the top surface of the bottom epitaxial layer 232 to prevent epitaxial deposition on the bottom epitaxial layer 232. In some embodiments not shown in FIG. 48, the bottom dielectric layer 2350 may partially or even completely cover sidewalls of the bottommost inner spacer features 234. In method 500, the bottom epitaxial layer 232 formed at block 502 functions to provide a smoother or flatter surface for the deposition of the bottom dielectric layer 2350. It has been observed that such smoother or flatter surface can lead to a bottom dielectric layer 2350 with increased integrity.

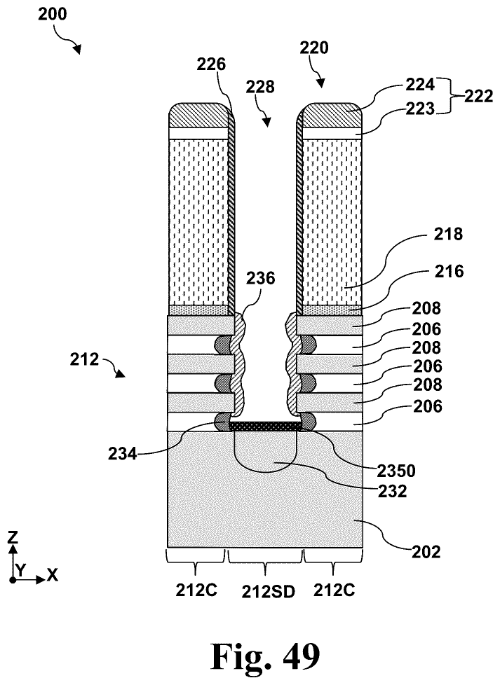

Referring to FIGS. 47 and 49, method 500 includes a block 506 where a reflowable epitaxial layer 236 is formed over the source/drain trench 228. With the bottom dielectric layer 2350 covering the bottom epitaxial layer 232, end surfaces of the channel layers 208 account for exposed semiconductor surfaces in the source/drain trench 228. This allows the reflowable epitaxial layer 236 to be selectively and epitaxially deposited on the exposed semiconductor surfaces of the channel layers 208. To ensure selective deposition of the reflowable epitaxial layer 236, the reflowable epitaxial layer 236 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the reflowable epitaxial layer 236 primarily on exposed semiconductor surfaces and the etch component (or etch cycles) removes the reflowable epitaxial layer 236 deposited on non-semiconductor surfaces. In some embodiments, the selective deposition of the reflowable epitaxial layer 236 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages.

In some embodiments, the reflowable epitaxial layer 236 may include silicon (Si) and germanium (Ge). In some embodiments, the reflowable epitaxial layer 236 may further include carbon (C) to reduce dopant diffusion. When the reflowable epitaxial layer 236 includes carbon (C), a carbon content in the reflowable epitaxial layer 236 may be smaller than 2%. The reflowable epitaxial layer 236 may be in-situ doped with an n-type dopant, such as phosphorus (P), arsenic (As), antimony (Sb), or a combination thereof. In terms of doping concentration, an arsenic (As) concentration in the reflowable epitaxial layer 236 may be smaller than 5×10²¹ atoms/cm³, a phosphorus (P) concentration in the reflowable epitaxial layer 236 may be smaller than 5×10²¹ atoms/cm³, and a antimony (Sb) concentration in the bottom epitaxial layer 232 may be smaller than 2×10²¹ atoms/cm³. When present, doping of the arsenic and antimony in the reflowable epitaxial layer 236 is more for diffusion control and less for resistance reduction while doping of phosphorus is more for resistance reduction. It is noted that while the source/drain feature 240 is n-type, the reflowable epitaxial layer 236 includes germanium (Ge). The presence of germanium (Ge) in the reflowable epitaxial layer 236 allows it to be reshaped at a temperature between about 600° C. and about 800° C. Through experiments and simulations, it has been found that temperature required to reshape a germanium-free epitaxial layer (e.g., an epitaxial layer that includes silicon) is substantially higher, such as greater than 1000° C. Such a high process temperature tends to cause damages to the device structures that have already been formed. In some embodiments, the reflowable epitaxial layer 236 may include germanium content between about 5% and about 60%. This range is not trivial. When the germanium content is smaller than 5%, it is not sufficient to lower the flowability temperature. When the germanium content is greater than 60%, the reflowable epitaxial layer 236 may have too greater a lattice mismatch with the channel members 2080 and a defect density in the reflowable epitaxial layer 236 may be too great to outweigh the benefits brought by the germanium content.

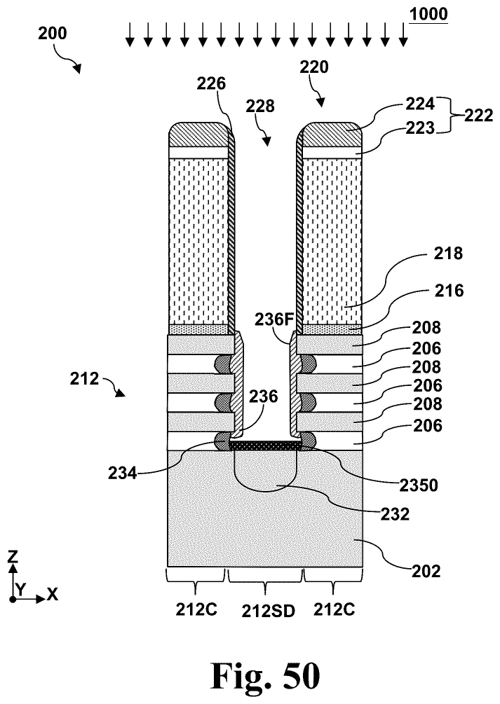

Referring to FIGS. 47 and 50, method 500 includes a block 508 where a thermal treatment 1000 is performed to reshape the reflowable epitaxial layer 236. In some embodiments, the thermal treatment 1000 may be a chemical-free treatment or a local thermal treatment, such as laser annealing. As shown in FIG. 50, the thermal treatment 1000 is performed to the reflowable epitaxial layer 236 to cause reshaping or reflowing to form a reshaped epitaxial layer 2360. In FIG. 50, the reshaped epitaxial layer 2360 may include two opposing flat surfaces 236F that are substantially vertical to the substrate 202. As shown in FIG. 50, the flat surfaces 236F of the reshaped epitaxial layer 2360 extends substantially along a depth of the source/drain trench 228, allowing unhindered passage to the bottom dielectric layer 235. In some embodiments represented in FIG. 50, the reshaped epitaxial layer 2360 is in direct contact with and spans vertically over end surfaces of all the channel layers 208 in the channel regions 212C.

Referring to FIGS. 47 and 51, method 500 includes a block 510 where a low-resistance epitaxial layer 238 is formed over the reshaped epitaxial layer 2360. After the reflowable epitaxial layer 236 is reshaped at block 508, the low-resistance epitaxial layer 238 is selectively deposited from surfaces of the reshaped epitaxial layer 2360. In some embodiments, the low-resistance epitaxial layer 238 may be deposited using vapor-phase epitaxy (VPE), ultra-high vacuum CVD (UHV-CVD), molecular beam epitaxy (MBE), and/or other suitable processes. Compared to the reflowable epitaxial layer 236, the low-resistance epitaxial layer 238 comprises a greater dopant concentration to reduce parasitic resistance. Because the reshaped epitaxial layer 2360 includes flat surfaces, rather than uneven shapes, the low-resistance epitaxial layer 238 is unlikely to prematurely merge to form voids in the low-resistance epitaxial layer 238. Different from the reflowable epitaxial layer 236, low-resistance epitaxial layer 238 is not subject to a thermal treatment for reshaping. In one embodiment, the low-resistance epitaxial layer 238 is free of germanium. In an alternative embodiment, the low-resistance epitaxial layer 238 includes silicon (Si) and carbon (C), where a carbon content in the low-resistance epitaxial layer 238 is smaller than 2%. The low-resistance epitaxial layer 238 includes an n-type dopant, such as arsenic (As), phosphorus (P), antimony (Sb), or a combination thereof. In terms of doping concentration, an arsenic (As) concentration in the low-resistance epitaxial layer 238 may be smaller than 5×10²¹ atoms/cm³, a phosphorus (P) concentration in the low-resistance epitaxial layer 238 may be smaller than 5×10²¹ atoms/cm³, and a antimony (Sb) concentration in the low-resistance epitaxial layer 238 may be smaller than 5×10²¹ atoms/cm³. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic and/or antimony, doping concentrations of arsenic and/or antimony in the reflowable epitaxial layer 236 are greater than those in the low-resistance epitaxial layer 238 because the reflowable epitaxial layer 236 is closer to the channel.

As shown in FIG. 51, the low-resistance epitaxial layer 238 extends vertically along the flat surfaces 236F into the reshaped epitaxial layer 2360. The low-resistance epitaxial layer 238 also vertically extends between a plurality of the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360. Both the reshaped epitaxial layer 2360 and the low-resistance epitaxial layer 238 are spaced apart from the bottom epitaxial layer 232 by the bottom dielectric layer 2350 and a bottom gap 2390. When method 500 is adopted, the source/drain feature 240 includes the reshaped epitaxial layer 2360 and the low-resistance epitaxial layer 238. The bottom epitaxial layer 232 is spaced apart from the source/drain feature 240 by the bottom dielectric layer 2350 and the bottom gap 2390. Method 550 in FIG. 52 is described below in conjunction with FIGS. 53-61.

Referring to FIGS. 52 and 53, method 550 includes a block 502 where a bottom epitaxial layer 232 is formed over the source/drain trench 228. Operation at block 502 has been described above with respect to method 500. Detailed description of the operations at block 502 is omitted for brevity.

Referring to FIGS. 52 and 53, method 550 includes a block 504 where a bottom dielectric layer 2350 is formed over the bottom epitaxial layer 232. Operation at block 504 has been described above with respect to method 500. Detailed description of the operations at block 504 is omitted for brevity.

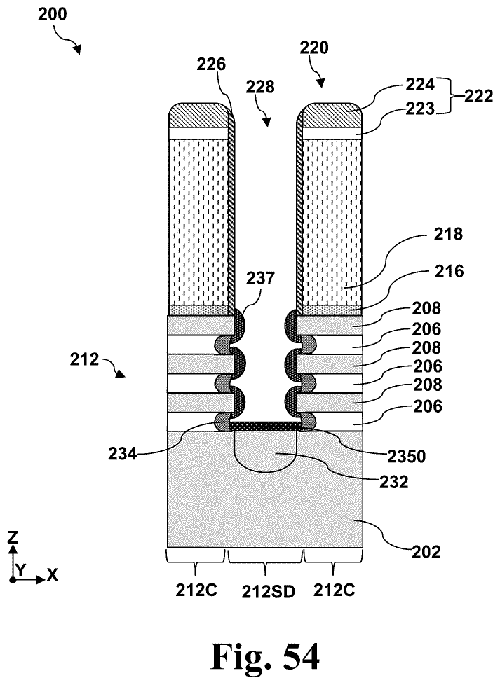

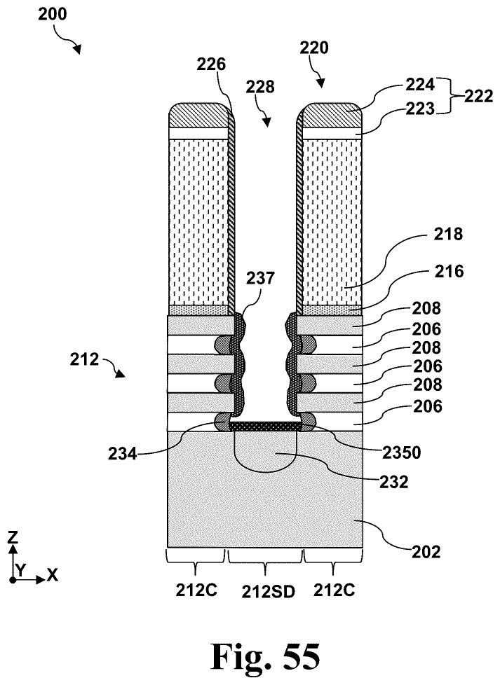

Referring to FIGS. 52, 54 and 55, method 550 includes a block 510 where an interface epitaxial layer 237 is deposited over the source/drain trench 228. With the bottom dielectric layer 2350 covering the bottom epitaxial layer 232, end surfaces of the channel layers 208 account for exposed semiconductor surfaces in the source/drain trench 228. This allows the interface epitaxial layer 237 to be selectively and epitaxially deposited on the exposed semiconductor surfaces of the channel layers 208. To ensure selective deposition of the interface epitaxial layer 237, the interface epitaxial layer 237 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the interface epitaxial layer 237 primarily on exposed semiconductor surfaces and the etch component (or etch cycles) removes the interface epitaxial layer 237 deposited on non-semiconductor surfaces. In some embodiments, the selective deposition of the interface epitaxial layer 237 may include vapor-phase epitaxy (VPE), ultra-high vacuum CVD (UHV-CVD), or molecular beam epitaxy (MBE), with a process pressure between about 1 Torr and about 760 Torr and a process temperature between about 600° C. and about 800° C. This process temperature range is not trivial. When the process temperature is below 600° C., the growth rate of the first epitaxial layer may be too slow. When the process temperature is above 800° C., the deposition process may cause damages. In some embodiments represented in FIG. 54, the interface epitaxial layer 237 deposited on the end surfaces of the channel layers 208 does not merge over the inner spacer features 234. In some alternative embodiments represented in FIG. 55, the interface epitaxial layer 237 deposited on the end surfaces of the channel layers 208 merges over the inner spacer features 234.

In some embodiments, the interface epitaxial layer 237 includes silicon (Si) and is free of germanium (Ge). In some embodiments, the interface epitaxial layer 237 may further include carbon (C) to reduce dopant out-diffusion. The interface epitaxial layer 237 may be in-situ doped with an n-type dopant, such as phosphorus (P), arsenic (As), antimony (Sb), or a combination thereof. In terms of doping concentration, n-type dopant concentration in the interface epitaxial layer 237 is smaller than that in the reflowable epitaxial layer 236 or the low-resistance epitaxial layer 238. An arsenic (As) concentration in the interface epitaxial layer 237 may be smaller than 5×10²¹ atoms/cm³, a phosphorus (P) concentration in the reflowable epitaxial layer 236 may be smaller than 5×10²¹ atoms/cm³, and a antimony (Sb) concentration in the interface epitaxial layer 237 may be smaller than 5×10²¹ atoms/cm³. When present, doping of the arsenic and antimony in the interface epitaxial layer 237 is more for diffusion control and less for resistance reduction while doping of phosphorus is more for resistance reduction. For that reason, a doping concentration of arsenic or antimony in the interface epitaxial layer 237 is greater than that in the subsequently formed reflowable epitaxial layer 236 or the low-resistance epitaxial layer 238.

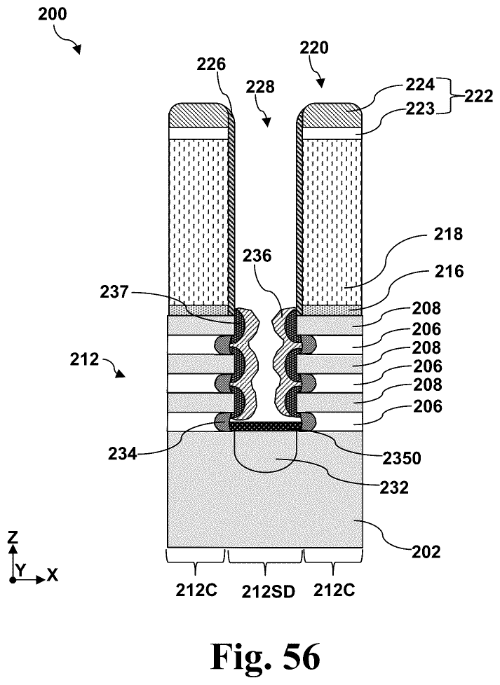

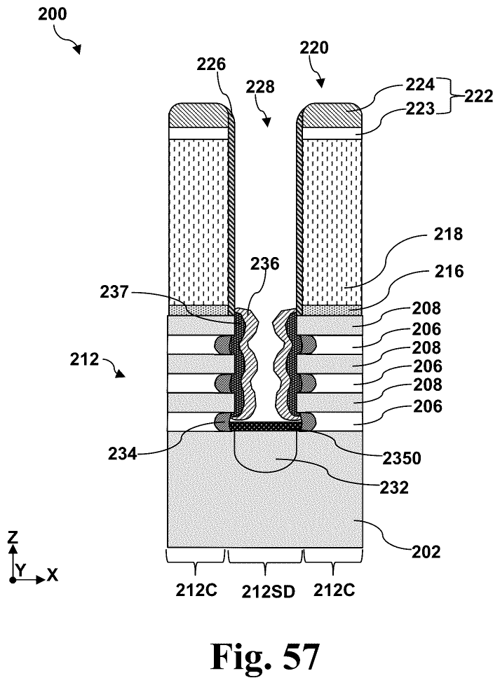

Referring to FIGS. 52, 56 and 57, method 550 includes a block 512 where a reflowable epitaxial layer 236 is formed over the interface epitaxial layer 237. Operation at block 512 is substantially similar to those described with respect to block 304 of method 300, except that, at block 512, the reflowable epitaxial layer 236 is deposited over the interface epitaxial layer 237 and is spaced apart from the bottom dielectric layer 2350. Detailed description of the operations at block 512 is omitted for brevity. FIG. 56 illustrates the reflowable epitaxial layer 236 deposited over the interface epitaxial layer 237 that does not merge over the inner spacer features 234. FIG. 57 illustrates the reflowable epitaxial layer 236 deposited over the interface epitaxial layer 237 that merges and spans continuously over the inner spacer features 234.

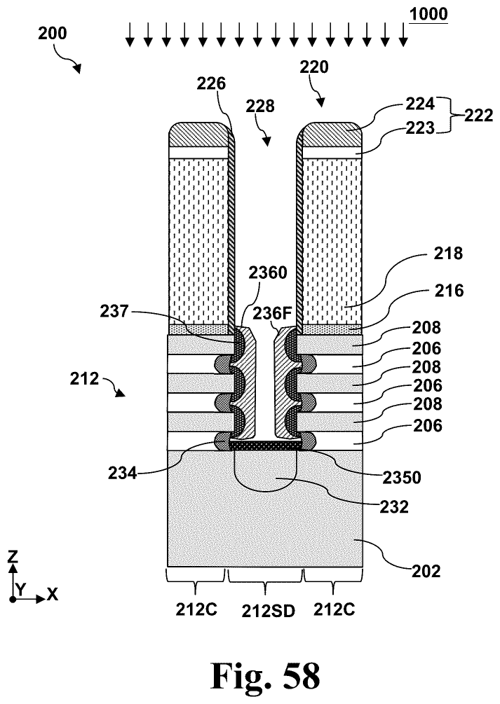

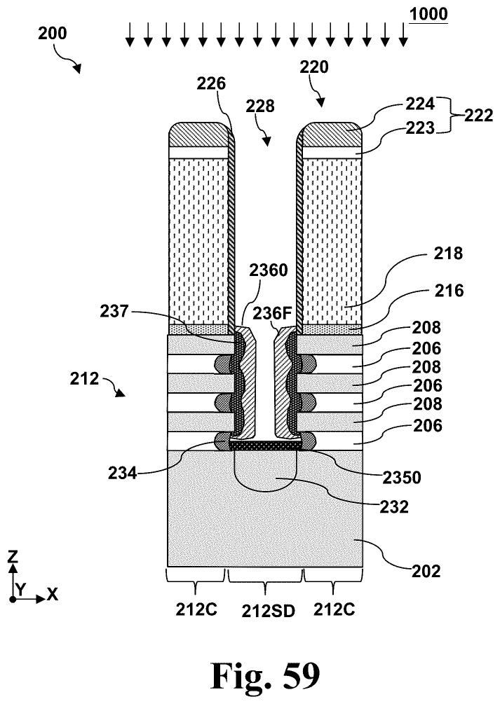

Referring to FIGS. 52, 58 and 59, method 550 includes a block 514 where a thermal treatment 1000 is performed to reshape the reflowable epitaxial layer 236. In some embodiments, the thermal treatment 1000 may be a chemical-free treatment or a local thermal treatment, such as laser annealing. As shown in FIGS. 58 and 59, the thermal treatment 1000 is performed to the reflowable epitaxial layer 236 to cause reshaping or reflowing to form a reshaped epitaxial layer 2360. FIG. 58 illustrates the reflowable epitaxial layer 236 being reshaped over the interface epitaxial layer 237 that does not merge over the inner spacer features 234. FIG. 59 illustrates the reflowable epitaxial layer 236 being reshaped over the interface epitaxial layer 237 that merges and spans continuously over the inner spacer features 234. In FIGS. 58 and 59, the reshaped epitaxial layer 2360 may include two opposing flat surfaces 236F that are substantially vertical to the substrate 202. As shown in FIGS. 58 and 29, the flat surfaces 236F of the reshaped epitaxial layer 2360 extends substantially along a depth of the source/drain trench 228, allowing unhindered passage to the bottom dielectric layer 2350.

Referring to FIGS. 52, 60 and 61, method 550 includes a block 516 where a low-resistance epitaxial layer 238 is formed over the reshaped epitaxial layer 2360. After the reflowable epitaxial layer 236 is reshaped at block 514, the low-resistance epitaxial layer 238 is selectively deposited from surfaces of the reshaped epitaxial layer 2360. In some embodiments, the low-resistance epitaxial layer 238 may be deposited using vapor-phase epitaxy (VPE), ultra-high vacuum CVD (UHV-CVD), molecular beam epitaxy (MBE), and/or other suitable processes. Compared to the reflowable epitaxial layer 236, the low-resistance epitaxial layer 238 comprises a greater dopant concentration to reduce parasitic resistance. Because the reshaped epitaxial layer 2360 includes flat surfaces, rather than uneven shapes, the low-resistance epitaxial layer 238 is unlikely to prematurely merge to form voids in the low-resistance epitaxial layer 238. Different from the reflowable epitaxial layer 236, low-resistance epitaxial layer 238 is not subject to a thermal treatment for reshaping. In one embodiment, the low-resistance epitaxial layer 238 is free of germanium. In an alternative embodiment, the low-resistance epitaxial layer 238 includes silicon (Si) and carbon (C), where a carbon content in the low-resistance epitaxial layer 238 is smaller than 2%. The low-resistance epitaxial layer 238 includes an n-type dopant, such as arsenic (As), phosphorus (P), antimony (Sb), or a combination thereof. In terms of doping concentration, an arsenic (As) concentration in the low-resistance epitaxial layer 238 may be smaller than 5×10²¹ atoms/cm³, a phosphorus (P) concentration in the low-resistance epitaxial layer 238 may be smaller than 5×10²¹ atoms/cm³, and a antimony (Sb) concentration in the low-resistance epitaxial layer 238 may be smaller than 5×10²¹ atoms/cm³. In terms of dopant composition, a phosphorus (P) doping concentration in the low-resistance epitaxial layer 238 is greater than a phosphorus (P) doping concentration in the reflowable epitaxial layer 236 to reduce parasitic resistance. When both the low-resistance epitaxial layer 238 and the reflowable epitaxial layer 236 include arsenic and/or antimony, doping concentrations of arsenic and/or antimony in the reflowable epitaxial layer 236 are greater than those in the low-resistance epitaxial layer 238 because the reflowable epitaxial layer 236 is closer to the channel.

As shown in FIGS. 60 and 61, the low-resistance epitaxial layer 238 extends vertically along the flat surfaces 236F into the reshaped epitaxial layer 2360. The low-resistance epitaxial layer 238 also vertically extends between a plurality of the horizontally-aligned channel layers 208 that will be released as channel members 2080 shown in FIG. 14. The low-resistance epitaxial layer 238 is spaced apart from the end surfaces of the channel layers 208 by the reshaped epitaxial layer 2360 and the interface epitaxial layer 237. The interface epitaxial layer 237, the reshaped epitaxial layer 2360 and the low-resistance epitaxial layer 238 are vertically spaced apart from the bottom epitaxial layer 232 by the bottom dielectric layer 2350 and a bottom gap 2390. When method 550 is adopted, the source/drain feature 240 includes the interface epitaxial layer 237, the reshaped epitaxial layer 2360 and the low-resistance epitaxial layer 238. The bottom epitaxial layer 232 is spaced apart from the source/drain feature 240 by the bottom dielectric layer 2350 and the bottom gap 2390.

In one exemplary aspect, the present disclosure is directed to a method. The method includes forming a fin-shaped structure over a substrate, the fin-shaped structure comprising a plurality of channel layers interleaved by a plurality of sacrificial layers, recessing a source/drain region of the fin-shaped structure to form a source/drain recess that exposes a portion of the substrate and sidewalls of the plurality of the channel layers, selectively and partially recessing sidewalls of the plurality of sacrificial layers to form inner spacer recesses, forming inner spacers in the inner spacer recesses, forming a bottom dielectric layer to cover the exposed portion of the substrate, depositing a first epitaxial layer over the inner spacers and the exposed sidewalls of the plurality of the channel layers, performing a thermal treatment to reshape the first epitaxial layer, after the performing of the thermal treatment, depositing a second epitaxial layer over the first epitaxial layer. The first epitaxial layer includes germanium and the second epitaxial layer is free of germanium.

In some embodiments, the first epitaxial layer further includes silicon and at least one n-type dopant. In some embodiments, the thermal treatment includes a temperature between about 600° C. and about 800° C. In some embodiments, the second epitaxial layer includes silicon, carbon, and at least one n-type dopant. In some embodiments, before the performing of the thermal treatment, the first epitaxial layer includes a wavy sidewall. After the performing of the thermal treatment, the wavy sidewall becomes a flat sidewall. In some instances, after the depositing of the second epitaxial layer, a bottom surface of the second epitaxial layer is spaced apart from the bottom dielectric layer by a gap. In some embodiments, the method further includes, before the depositing of the first epitaxial layer, depositing an interface epitaxial layer over the inner spacers and the exposed sidewalls of the plurality of the channel layers. In some embodiments, the interface epitaxial layer is free of germanium. In some implementations, the interface epitaxial layer includes silicon, carbon, and at least one n-type dopant.

In another exemplary aspect, the present disclosure is directed to a method. The method includes forming a fin-shaped structure over a substrate, the fin-shaped structure comprising a plurality of channel layers interleaved by a plurality of sacrificial layers, recessing a source/drain region of the fin-shaped structure to form a source/drain recess that exposes a portion of the substrate and sidewalls of the plurality of the channel layers, selectively and partially recessing sidewalls of the plurality of sacrificial layers to form inner spacer recesses, forming inner spacers in the inner spacer recesses, forming a bottom epitaxial layer to cover the exposed portion of the substrate, depositing a first epitaxial layer over the inner spacers and the exposed sidewalls of the plurality of the channel layers, performing a thermal treatment to reshape the first epitaxial layer, after the performing of the thermal treatment, depositing a second epitaxial layer over the first epitaxial layer. The first epitaxial layer includes germanium and the second epitaxial layer is free of germanium.

In some embodiments, the bottom epitaxial layer includes silicon, carbon, arsenic, phosphorus, antimony, or boron. In some implementations, the first epitaxial layer further includes silicon and at least one n-type dopant. In some embodiments, the thermal treatment includes a temperature between about 600° C. and about 800° C. In some embodiments, the second epitaxial layer includes silicon, carbon, and at least one n-type dopant. In some embodiments, the method further includes, before the depositing of the first epitaxial layer, depositing an interface epitaxial layer over the inner spacers and the exposed sidewalls of the plurality of the channel layers. The interface epitaxial layer is free of germanium.

In yet another exemplary aspect, the present disclosure is directed to a semiconductor structure. The semiconductor structure includes a base fin rising from a substrate, a first plurality of nanostructures disposed over a first channel region of the base fin, a second plurality of nanostructures disposed over a second channel region of the base fin, and a source/drain feature disposed between and in contact with the first plurality of nanostructures and the second plurality of nanostructures. The source/drain feature includes a bottom epitaxial layer extending into the base fin, a first epitaxial layer in direct contact with the first plurality of nanostructures, the second plurality of nanostructures, and the bottom epitaxial layer, a second epitaxial layer disposed over the first epitaxial layer, and a third epitaxial layer disposed over the second epitaxial layer. The first epitaxial layer and the third epitaxial layer are free of germanium and the second epitaxial layer includes germanium.

In some embodiments, the second epitaxial layer includes two flat surfaces to engage the third epitaxial layer. In some embodiments, the two flat surfaces vertically span over at least two of the first plurality of nanostructures and at least two of the second plurality of nanostructures. In some embodiments, a portion of the third epitaxial layer extends between at least two of the first plurality of nanostructures and at least two of the second plurality of nanostructures. In some embodiments, the bottom epitaxial layer includes silicon, carbon, arsenic, phosphorus, antimony, or boron.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure over a substrate, the fin-shaped structure comprising a plurality of channel layers interleaved by a plurality of sacrificial layers;
recessing a source/drain region of the fin-shaped structure to form a source/drain recess that exposes a portion of the substrate and sidewalls of the plurality of the channel layers;
selectively and partially recessing sidewalls of the plurality of sacrificial layers to form inner spacer recesses;
forming inner spacers in the inner spacer recesses;
forming a bottom dielectric layer to cover the exposed portion of the substrate;
depositing a first epitaxial layer over the inner spacers and the exposed sidewalls of the plurality of the channel layers;
performing a thermal treatment to reshape the first epitaxial layer;
after the performing of the thermal treatment, depositing a second epitaxial layer over the first epitaxial layer,
wherein the first epitaxial layer comprises germanium,
wherein the second epitaxial layer is free of germanium.

2. The method of claim 1, wherein the first epitaxial layer further comprises silicon and at least one n-type dopant.

3. The method of claim 1, wherein the thermal treatment comprises a temperature between about 600° C. and about 800° C.

4. The method of claim 1, wherein the second epitaxial layer comprises silicon, carbon, and at least one n-type dopant.

5. The method of claim 1,
wherein, before the performing of the thermal treatment, the first epitaxial layer comprises a wavy sidewall,
wherein, after the performing of the thermal treatment, the wavy sidewall becomes a flat sidewall.

6. The method of claim 1, wherein, after the depositing of the second epitaxial layer, a bottom surface of the second epitaxial layer is spaced apart from the bottom dielectric layer by a gap.

7. The method of claim 1, further comprising:
before the depositing of the first epitaxial layer, depositing an interface epitaxial layer over the inner spacers and the exposed sidewalls of the plurality of the channel layers.

8. The method of claim 7, wherein the interface epitaxial layer is free of germanium.

9. The method of claim 7, wherein the interface epitaxial layer comprises silicon, carbon, and at least one n-type dopant.

10. A method, comprising:
forming a fin-shaped structure over a substrate, the fin-shaped structure comprising a plurality of channel layers interleaved by a plurality of sacrificial layers;
recessing a source/drain region of the fin-shaped structure to form a source/drain recess that exposes a portion of the substrate and sidewalls of the plurality of the channel layers;
selectively and partially recessing sidewalls of the plurality of sacrificial layers to form inner spacer recesses;
forming inner spacers in the inner spacer recesses;
forming a bottom epitaxial layer to cover the exposed portion of the substrate;
depositing a first epitaxial layer over the inner spacers and the exposed sidewalls of the plurality of the channel layers;
performing a thermal treatment to reshape the first epitaxial layer;
after the performing of the thermal treatment, depositing a second epitaxial layer over the first epitaxial layer,
wherein the first epitaxial layer comprises germanium,
wherein the second epitaxial layer is free of germanium.

11. The method of claim 10, wherein the bottom epitaxial layer comprises silicon, carbon, arsenic, phosphorus, antimony, or boron.

12. The method of claim 10, wherein the first epitaxial layer further comprises silicon and at least one n-type dopant.

13. The method of claim 10, wherein the thermal treatment comprises a temperature between about 600° C. and about 800° C.

14. The method of claim 10, wherein the second epitaxial layer comprises silicon, carbon, and at least one n-type dopant.

15. The method of claim 10, further comprising:
before the depositing of the first epitaxial layer, depositing an interface epitaxial layer over the inner spacers and the exposed sidewalls of the plurality of the channel layers,
wherein the interface epitaxial layer is free of germanium.

16. A semiconductor structure, comprising:
a base fin rising from a substrate;
a first plurality of nanostructures disposed over a first channel region of the base fin;
a second plurality of nanostructures disposed over a second channel region of the base fin; and
a source/drain feature disposed between and in contact with the first plurality of nanostructures and the second plurality of nanostructures,
wherein the source/drain feature comprises:
a bottom epitaxial layer extending into the base fin,
a first epitaxial layer in direct contact with the first plurality of nanostructures, the second plurality of nanostructures, and the bottom epitaxial layer,
a second epitaxial layer disposed over the first epitaxial layer, and
a third epitaxial layer disposed over the second epitaxial layer,
wherein the first epitaxial layer and the third epitaxial layer are free of germanium,
wherein the second epitaxial layer comprises germanium.

17. The semiconductor structure of claim 16, wherein the second epitaxial layer comprises two flat surfaces to engage the third epitaxial layer.

18. The semiconductor structure of claim 17, wherein the two flat surfaces vertically span over at least two of the first plurality of nanostructures and at least two of the second plurality of nanostructures.

19. The semiconductor structure of claim 16, wherein a portion of the third epitaxial layer extends between at least two of the first plurality of nanostructures and at least two of the second plurality of nanostructures.

20. The semiconductor structure of claim 16, wherein the bottom epitaxial layer comprises silicon, carbon, arsenic, phosphorus, antimony, or boron.
